(19) United States
(12) Patent Application Publication
(10) Pub. No.: US 2025/0254376 A1
(43) Pub. Date: Aug. 7, 2025

(54) DATA TRANSLATION FOR VIDEO-VIEWING ACTIVITY

(71) Applicant: Comcast Cable Communications, LLC, Philadelphia, PA (US)

(72) Inventor: Robert Alan Orlowski, Centennial, CO (US)

(21) Appl. No.: 19/191,184

(22) Filed: Apr. 28, 2025

Related U.S. Application Data
(63) Continuation of application No. 18/173,180, filed on Feb. 23, 2023, now Pat. No. 12,316,895.
Application No. 18/173,180 is a continuation of application No. 14/037,352, filed on Sep. 25, 2013, now Pat. No. 11,627,356.

(51) Int. Cl. H04N 21/258; H03M 7/30; H04N 21/442; H04N 21/658

(52) U.S. Cl. CPC H04N 21/258; H03M 7/30; H04N 21/44222; H04N 21/6582; H04N 21/44226

(57) ABSTRACT

Methods, systems and apparatuses are described for using Linear, DVR, and VOD video viewing activity data for more efficient downstream processing to create analytical studies of second-by-second viewing activity for program, channel, house, device, viewer, demographic, and geographic attributes. Such attributes may be determined for one or more viewing devices. Attributes associated with different viewing devices may be replaced with a common substitute value. Video viewing metrics associated with a common substitute value may be determined.

### CROSS-REFERENCE TO RELATED APPLICATIONS

This application is a continuation of and claims priority to U.S. patent application Ser. No. 18/173,180, filed Feb. 23, 2023, which is a continuation of U.S. patent application Ser. No. 14/037,352, filed Sep. 25, 2013 (now U.S. Pat. No. 11,627,356), each of which is hereby incorporated by reference in its entirety.

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### BACKGROUND

### Prior Art

I have not found any relevant prior art at the present time.

### BACKGROUND INFORMATION

### General Statement of Problem

With the ever increasing number of consumer choices for television viewing, it is important for advertisers, content producers, and service providers such as cable television and satellite television and internet protocol television companies to be able to accurately measure audience viewership. I have discussed this problem extensively in my prior applications. In two of my previous Applications, I have taught how to use the MapReduce Framework to aggregate video viewing activity. When using that framework an analyst may find that certain aggregation functions consume a large quantity of computing resources but do not add value commensurate with that consumption of resources. This application teaches how to reduce the workload on the MapReduce Framework by implementing various data translation strategies prior to sending the video viewing activity file to downstream processes for measuring or aggregating Linear, DVR, and VOD Second-By-Second Video Viewing Activity. The reader will readily recognize that these aggregation strategies are applicable to a wide range of video content including, but not limited to, cable and/or satellite television video on demand, all variety of video content delivered electronically across a network, and online educational videos.

### Existing Tools for Data Analysis

In my prior applications U.S. application Ser. No. 14/013,031 filed on Aug. 29, 2013 and U.S. application Ser. No. 14/020,778 filed on Sep. 6, 2013 I taught how to aggregate video viewing activity and video program viewing activity using the MapReduce Framework. I have not found any other teachings on this topic.

### SUMMARY

In accordance with one embodiment, I disclose a computer-implemented method of using Linear, DVR, and VOD video viewing activity data as input to a data translation processor which prepares that video viewing activity for more efficient downstream processing by translating detailed values to aggregated values according to analyst defined translation rules in preparation for ingestion by a MapReduce Framework with the result that the MapReduce Framework needs to process less data in order to create analytical studies of second-by-second viewing activity for program, channel, house, device, viewer, demographic, and geographic attributes in combination or as individual attributes. Once the data translation rules have been applied to the video viewing activity by the data translation processor, the data is ready for use by downstream tools such as the MapReduce Framework which is able to aggregate the data much more efficiently than would have been possible prior to running the data translation processor. Additionally, by applying the translations to the video viewing activity file which contains all of the detailed values, this enables the analyst to use a single copy of that file for multiple analytical studies thus avoiding the time and cost associated with creating a new extract file with embedded translated values for each analytical study.

### ADVANTAGES

By implementing the data translation processor that I teach about in this Application, an analyst can produce video viewing aggregations using the MapReduce distributed computing framework in less time using less computing resources. This will allow the analyst to aggregate larger data sets than would otherwise be possible using a given set of computer hardware. It will also allow the analyst to run additional studies thus potentially gaining additional insights into viewing behaviors.

Additionally, the analyst is able to save significant time and computing resources by avoiding the need to recreate the video viewing activity file with multiple data translations embedded in it because he does not need a new extract from the source system for each analytical study.

### DEFINITIONS

The following are definitions that will aid in understanding one or more of the embodiments presented herein:

Computer readable format means any data format that can be read by a computer program or a human being as necessary. Nonlimiting examples include:
(i) formatted text files,
(ii) pipe delimited text files,
(iii) data base tables,
(iv) Extensible Markup Language (XML) messages,
(v) a printed report,
(vi) JavaScript Object Notation messages.

Data analysis computer system means a combination of one or more computers on which a Data Translation Program or Programs can be executed. Nonlimiting examples include:
(i) one or more computers where video viewing activity data can be used as input to a process which creates prepared video viewing activity data.

Data analysis computer of known type means any commonly available computer system running a commonly known operating system. Nonlimiting examples include:
(i) a standard personal computer running WINDOWS 7 Professional operating system from MICROSOFT® Corporation,
(ii) a computer running the UNIX operating system,
(iii) a computer running the Linux operating system,
(iv) a computer in a cloud computing environment,
(v) a mainframe computer with its operating system.

Data translation program means a computer program or programs that are able to execute on a Data analysis computer of known type. Nonlimiting examples include:
(i) a JAVA program, (ii) a Python script, (iii) a COBOL program.

Demographic information means any data item that can describe a characteristic of a viewer or a subscriber or a household associated with a viewer who is operating the video asset viewing device. Non-limiting examples include income, ethnicity, gender, age, marital status, location, geographic area, postal code, census data, occupation, social grouping, family status, any proprietary demographic grouping, segmentation, credit score, dwelling type, homeownership status, property ownership status, rental status, vehicle ownership, tax rolls, credit card usage, religious affiliation, sports interest, political party affiliation, cable television subscriber type, cable television subscriber package level, and cell phone service level.

Device Characteristic means any feature or capability or aspect or descriptive qualifier or identifier of a video viewing device. Nonlimiting examples include that this may identify the type of device such as a set-top box, a tablet, a smart phone; a capability of the device such as the ability to record video or to support multiple viewing windows, or a manufacturer identifier.

Device Type is a subset of Device Characteristic where device type may, as a nonlimiting example, identify the type of device such as a set-top box, a tablet, a smart phone.

Digital Video Recorder means a device that records video content from a network for later playback. This includes but is not limited to set-top box DVR, network DVR, and cloud DVR.

DVR—see Digital Video Recorder.

Digital Video Recording (DVR) Playback is when the viewer plays back content that was previously recorded on their DVR. DVR content can be viewed using various Trick Play features.

Geographic information means any service area or any network hierarchy designation or marketing area or other designated area used by a cable television company or a satellite television company or IP Television delivery company or educational service provider or video asset delivery system. The boundary or description of a geographic area is defined based on the needs of the service provider. Nonlimiting examples include a Market in a cable company network, a Headend in a cable company network, a Hub in a cable company network, a census tract, a cell tower identifier, a service area for satellite TV, advertising zone, a zip code, or some other geographic identifier. The geographic information may then be used to identify the location of a video asset viewing device or geographic information about the about the house associated with the device or the location of the device at the time of the viewer interaction in the event that the viewer interaction occurs in a location different than the location of the house associated with the device.

Network means any computer network. Nonlimiting examples include:
(i) a cable television network,
(ii) a cellular telephony network,
(iii) hybrid fiber coax system,
(iv) a satellite television network,
(v) a wi-fi network,
(vi) any means that supports communication among video asset viewing devices or electronic devices or computers or computer systems.

Pipe delimited text files means data files where the fields are separated by the “I” character.

New form of said video viewing activity data means the prepared version of the Video Viewing Activity Data File.

Sessionized Linear Viewing is linear tuning activity which has been transformed into program based viewing. A simple linear tuning event may cross program boundaries. That simple linear tuning event can be split into multiple program based linear viewing activity records by creating separate tuning records for each program that is viewed during the linear tuning event. The viewer may use “trick plays” when viewing this content. Additionally, the sessionized linear viewing may represent live viewing activity or time shifted viewing activity.

Set-top box means a video asset viewing device that receives external signals and decodes those signals into content that can be viewed on a television screen or similar display device. The signals may come from a cable television system, a satellite television system, a network, or any other suitable means. A set-top box may have one or more tuners. The set-top box allows the user to interact with it to control what is displayed on the television screen. The set-top box is able to capture the commands given by the user and then transmit those commands to another computer system. For purposes of this application, stating that a set-top box tunes to a channel is equivalent to stating that a tuner in a set-top box has tuned to a channel. A set-top box may also play back previously recorded video content. STB means Set-top box.

Trick Play means using features of the video viewing device to execute operations such as Play, Fast Forward at various speeds (1×, 2×, 3×, 4×), Pause, Skip, Reverse at various speeds (1×, 2×, 3×, 4×), Slow play, slow reverse, and similar activities.

Tuner means a tuner in a Set-top box.

Tuner index means an identifier of a tuner in a Set-top box.

Video On Demand (VOD) a video service whereby previously recorded video content is made available for viewing. VOD content can be viewed using various Trick Play features. The content may include, but is not limited to, cable and/or satellite television video on demand, all variety of video content delivered electronically across a network, and online educational videos.

Video asset means any programming content that may be viewed and/or heard. A Video Program may contain multiple Video Assets. Nonlimiting examples of Video Asset include:
(i) advertisements or commercials, (ii) movies, (iii) sports programs, (iv) news casts, (v) music,
(vi) television programs, (vii) video recordings.

Video asset viewing device means any electronic device that may be used either directly or indirectly by a human being to interact with video content where the video content is provided by a cable television system or a satellite television system or a computer system accessed through a network. Nonlimiting examples include: Gaming station, web browser, MP3 Player, Internet Protocol phone, Internet Protocol television, mobile device, mobile smart phone, set-top box, satellite television receiver, set-top box in a cable television network, set-top box in a satellite television system, cell phone, personal communication device, personal video recorder, personal video player, two-way interactive service platforms, personal computer, tablet device.

Video server delivering video content through a network means any computer system, any individual piece of computer equipment or electronic gear, or any combination of computer equipment or electronic gear which enables or facilitates the viewer interaction with the video asset viewing device. Nonlimiting examples include:
(i) cable television system, (ii) cable television switched digital video system,
(iii) cellular phone network, (iv) satellite television system, (v) web server,
(vi) any individual piece of computer equipment or electronic gear,
(vii) any combination of computer equipment or electronic gear.

Video viewing activity means any identifiable activity that a Video asset viewing device operator may do in regard to a Video asset viewing device and where such activity can be captured by the video asset viewing device or by the video server delivering video content through a network that supports the device. Nonlimiting examples include:
(i) power on/power off, open web page, close web page,
(ii) channel up/channel down/channel selection, play video content on web browser,
(iii) volume up/volume down/mute/unmute,
(iv) any trick play such as fast forward, rewind, pause
(v) recording video content,
(vi) playing back recorded video content,
(vii) invoking a menu, choosing a menu option,
(viii) any response to a screen prompt
(ix) playing live video content.

Viewer means the human being causing a Viewer interaction; the user of a Set-top box or a Video asset viewing device.

### BRIEF DESCRIPTION OF THE DRAWINGS

The present disclosure is illustrated by way of example and not limited in the accompanying figures in which like reference numerals indicate similar elements and in which:

FIG. 1 depicts a computing system having a primary computing component and one or more associated computing components in accordance with one or more example embodiments.

FIG. 2 depicts an illustrative operating environment in which various aspects of the disclosure may be implemented in accordance with one or more example embodiments.

FIG. 3 depicts an illustrative block diagram of workstations and servers that may be used to implement the processes and functions of certain aspects of the present disclosure in accordance with one or more example embodiments.

FIG. 4 shows a flowchart for provisioning and enabling a user to obtain service by an application on an associated computing component in accordance with one or more example embodiments.

FIG. 5 depicts an illustrative computing environment for provisioning a group or user for service provided by an application on an associated computing component in accordance with one or more example embodiments.

FIG. 6 depicts an illustrative computing environment for batch process for enabling a user to obtain service by an application on an associated computing component in accordance with one or more example embodiments.

FIG. 7 depicts an illustrative event sequence for provisioning a group or user for service provided by an application on an associated computing component in accordance with one or more example embodiments.

FIG. 8 depicts an illustrative event sequence for obtaining a security token for service by an application on an associated computing component in accordance with one or more example embodiments.

FIG. 9 depicts an illustrative event sequence for obtaining a service ticket for service by an application on an associated computing component in accordance with one or more example embodiments.

FIG. 10 shows a flowchart for provisioning a group or user for obtaining service by an application on an associated computing component in accordance with one or more example embodiments.

FIG. 11 shows a flowchart for batch process for enabling a user to obtain service by an application on an associated computing component in accordance with one or more example embodiments.

FIG. 12 shows a flowchart for setup script in accordance with one or more example embodiments.

### DETAILED DESCRIPTION OF THE DRAWINGS

When reading the information below, it can be appreciated that these are merely samples of table layouts, format and content, and many aspects of these tables may be varied or expanded within the scope of the embodiment. The table layouts, field formats and content, algorithms, and other aspects are what I presently contemplate for this embodiment, but other table layouts, field formats and content, algorithms, etc. can be used. The algorithms are samples and various aspects of the algorithms may be varied or expanded within the scope of the embodiment.

In one embodiment the Channel Translation Processor 150 and the Data Translation Processor 154 can be implemented on computer clusters accessing a distributed file system under the Linux operating system. The Channel Translation Processor 150 and the Data Translation Processor 154 can each be implemented in JAVA or Python or COBOL or various other languages. Those skilled in the art will readily recognize these tools.

### Note on Media Measurement Data Model

Cable Television Laboratories, Inc. has published an “Audience Data Measurement Specification” as “OpenCable™ Specifications, Audience Measurement, Audience Measurement Data Specification” having Document Control Number “OC-SP-AMD-I01-130502” copyright© Cable Television Laboratories, Inc. 2013 which describes a Media Measurement Data Model (MMDM) database design which can be used as a source of data for both Channel Translation.

Processor 150 and the Data Translation Processor 154 which I teach how to build in this Application. The teaching in my present application can be implemented in conjunction with that Media Measurement Data Model or with any number of data models as long as the required input data is provided as described herein.

Note: Numbering in the Drawings—The numbers in the drawings are usually, but not always, in sequential order.

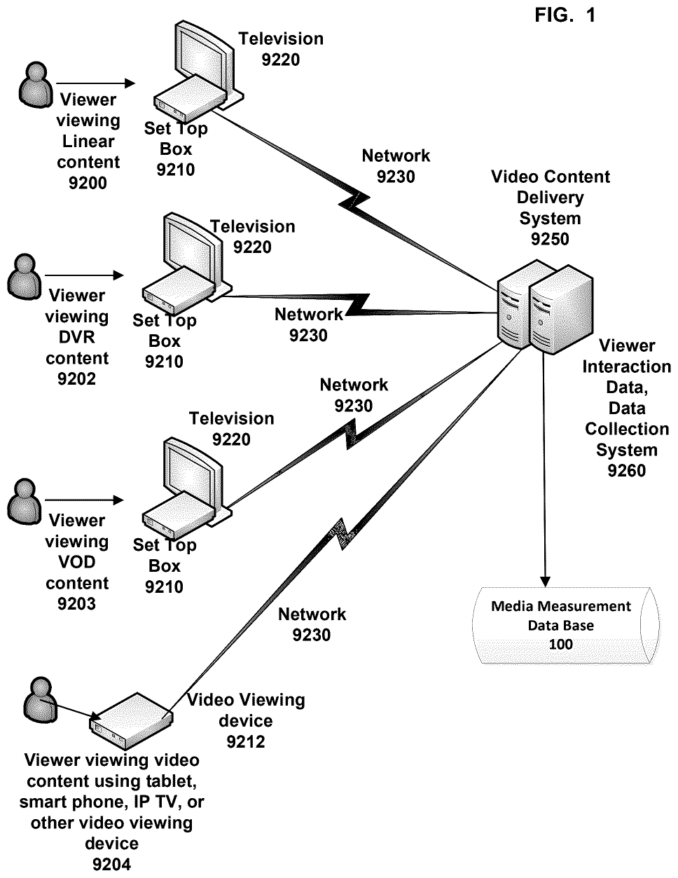

FIG. 1 provides an overview of an exemplary process for collecting viewer interaction data derived from a plurality of viewers interacting with video content that was delivered on a plurality of video asset viewing devices delivering content through a network and then loading that data to a Media Measurement Data Base 100. This figure illustrates several viewers interacting with video asset viewing devices to view content which was delivered to those devices across a network and then to collect viewing activity from those devices.

In this nonlimiting example, the purpose is not to describe in detail the operations of a video content delivery network or a data collection process, but simply to show how the data that is collected from that system can be made available to my Channel Translation Processor 150 or my Data Translation Processor 154.

It begins with Viewer Viewing Linear Content 9200 who is interacting with a set-top box 9210 and television 9220 as he views linear content. The set-top box 9210 interacts with a Video Content Delivery System 9250 which delivers the content across a Network 9230.

It continues with Viewer Viewing DVR Content 9202 who is interacting with a set-top box 9210 and television 9220 as he interacts with DVR content, recording content and playing back recorded content using various modes including trick plays. The set-top box 9210 interacts with a Video Content Delivery System 9250 which delivers the content across a Network 9230.

It continues with Viewer Viewing VOD Content 9203 who is interacting with a set-top box 9210 and television 9220 as he interacts with VOD content, playing the content using various modes including trick plays. The set-top box 9210 interacts with a Video Content Delivery System 9250 which delivers the content across a Network 9230.

It continues with Viewer viewing video content using tablet, smart phone, IP TV, or other video viewing device 9204 who is interacting with a variety of Video Viewing Devices 9212, including but not limited to tablet, smart phone, IP TV, PC, etc. The video viewing device interacts with a Video Content Delivery System 9250 which delivers the content across a Network 9230.

Video Content Delivery System 9250 then interacts with a Viewer Interaction Data, Data Collection System 9260 which collects all manner of viewer interaction data including Linear viewing including time-shifted linear viewing, Digital Video Recorder recording and playback/viewing, Video on Demand viewing, Educational video viewing, Streaming video viewing, and Live viewing. The Viewer Interaction Data, Data Collection System 9260 then processes the data as needed to load it to a Media Measurement Data Base 100. The data in the Media Measurement Data Base 100 can then be used as input to creating the Video Viewing Activity Data File 130, as described in FIG. 2.

FIG. 2 illustrates an overview of the process for creating the Video Viewing Activity Data File 130. The process of extracting this file from the Media Measurement Database 100 is often an expensive operation. For this reason, an analyst may wish to create this file in a somewhat generalized format with numerous detail fields and then store the file on a distributed file system in preparation for running a variety of analytical processes against the file.

As a non-limiting example, a file of Video Viewing Activity Data may be used to analyze viewing in numerous dimensions such as:

| | | |
|---|---|---|
| (i) program | (ii) channel | (iii) house |
| information, | information, | information, |
| (iv) device | (v) viewer | (vi) geographic |
| information, | information, | information, |
| (vii) demographic | | |
| information. | | |

To provide a number of non-limiting examples, for program information, the analyst may need to:
a) Analyze sports viewing vs. all other viewing
b) Analyze News viewing vs. sports viewing
c) Analyze Sports viewing vs. movie viewing
d) Analyze “G” program viewing vs. all other viewing.

To provide a number of non-limiting examples, for channel information, the analyst may need to:
a) Analyze standard definition viewing vs. high definition viewing of a channel
b) Analyze all standard definition viewing vs. all high definition viewing
c) Combine standard definition viewing and high definition viewing to measure that
d) Analyze combined standard definition viewing and high definition viewing of one channel vs. all other channels.

To provide a number of non-limiting examples, for house information, the analyst may need to:
a) Analyze residential viewing vs. commercial viewing
b) Analyze house viewing vs. apartment (multi-family) viewing.

To provide a number of non-limiting examples, for device information, the analyst may need to:
a) Analyze STB viewing vs. all other viewing
b) Analyze STB viewing vs. tablet viewing.

To provide a number of non-limiting examples, for viewer information, the analyst may need to:
a) Analyze viewing by viewer type such as parent vs. student
b) Analyze viewing by grade level.

To provide a number of non-limiting examples, for geographic information, the analyst may need to:
a) Analyze viewing by a combination of zip codes
b) Analyze viewing by one marketing area compared to another marketing area.

To provide a number of non-limiting examples, for demographic information, the analyst may need to:
a) Analyze viewing by a combination of age levels
b) Analyze viewing by one education level vs. another education level
c) Analyze viewing by one education level vs. all other education levels.

In addition to all of these possibilities, an analyst may combine any number of these qualifiers. To provide a number of non-limiting examples, for demographic information, the analyst may need to:
a) Analyze viewing of a channel by a combination of age levels
b) Analyze viewing of a channel by device types
c) Analyze viewing by a program by demographic groups
d) Analyze viewing by a program by demographic groups by device types.

In each of the examples above, the analyst may be able to take the same Video Viewing Activity Data File 130 that was extracted from the Media Measurement Database 100 and use it, with various enrichments, to feed into a MapReduce process where he can aggregate the data using hundreds or even thousands of computers working in parallel. Those skilled in the art will readily recognize that when there are fewer unique keys to aggregate using MapReduce, the MapReduce process will consume fewer resources, thus allowing the analyst to complete more studies in less time with less computing resources.

To explain this further, in my pending applications U.S. application Ser. No. 14/013,031 filed on Aug. 29, 2013 and U.S. application Ser. No. 14/020,778 filed on Sep. 6, 2013 I taught how to use the MapReduce distributed computing framework to analyze video viewing activity. In those applications I taught how to explode the video viewing activity so that one record is created for each second of viewing activity for each incoming record.

If an analyst was analyzing 3600 seconds of viewing across 100 channels, this could potentially lead to 3600*100=360,000 unique keys in the Reduce part of the MapReduce process. However, if the analyst knew in advance that he was only interested in detailed viewing information for 10 channels and all the other activity could be grouped into an “OTHER” bucket, then this could potentially lead to 3600*11=39,600 unique keys in the Reduce part of the MapReduce process. This is a very large reduction in the unique key count which results in a significant reduction in run time and computing resources needed to run the analysis.

Similarly, suppose there is a cable system with 300 channels. If an analyst was interested in analyzing the viewing activity of 20 channel across the entire day of 86,400 seconds, he would likely still need to measure the viewing activity of all the other 280 channels, perhaps to be able to calculate the percentage of the overall viewing activity at any second of the day for each of the 20 channels. In this case assume the analyst is not interested in the activity of those other channels except to have an accurate count of total viewing during any second of the day. If the analyst simply aggregated the incoming data as it is, the result could potentially be 300*86,400=25,920,000 unique keys in the Reduce part of the MapReduce process. By grouping the viewing activity of the 280 channels into an “OTHER” bucket, then this could potentially lead to 86,400*21=1,814,400 unique keys in the Reduce part of the MapReduce process. This is a very large reduction in the unique key count which results in a significant reduction in run time and computing resources needed to run the analysis.

This same thought process applies to program information, house information, device information, viewer information, geographic information, and demographic information. Thus we see that the same extract file can be used in a multitude of analytical processes if the analyst is able to apply some pre-aggregation rules to the file to create a Prepared Video Viewing Activity Data File. In the remainder of this specification I will teach how to create such an Prepared Video Viewing Activity Data File which can then be provided to downstream analytic processes such as the Data Explosion Process described in my previous Applications.

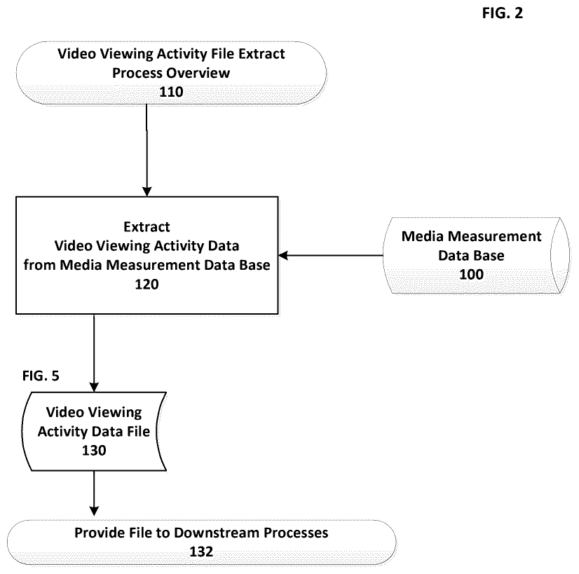

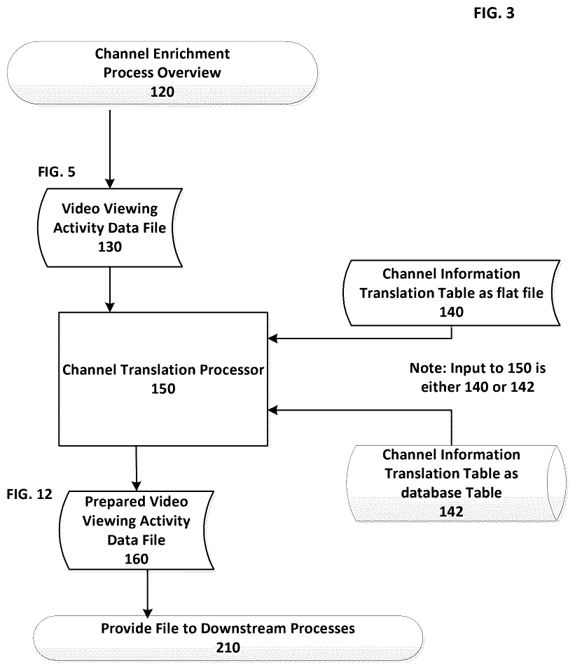

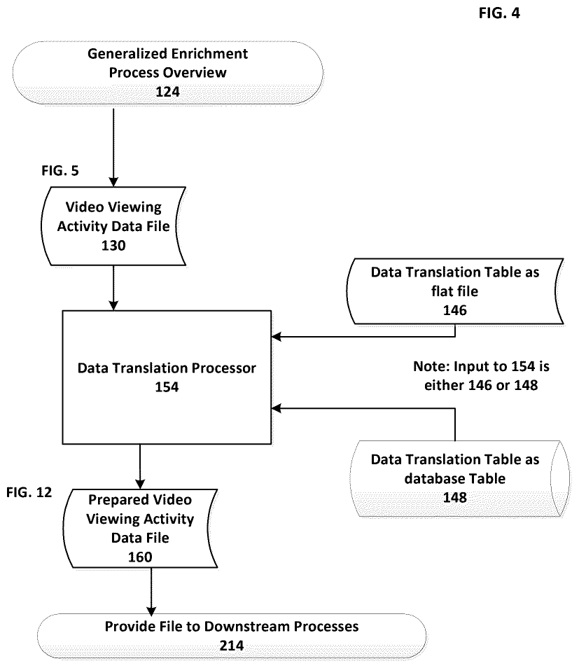

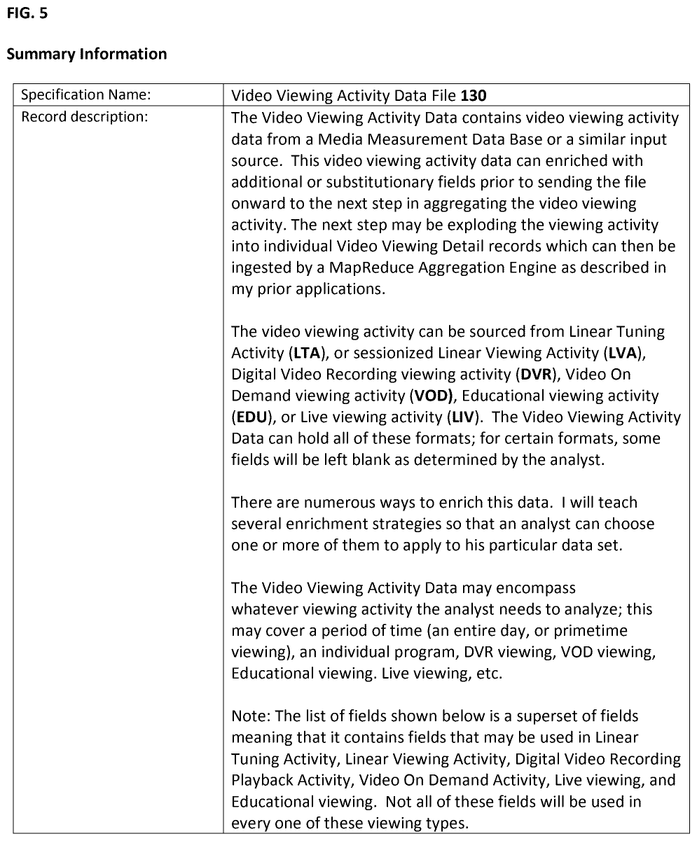

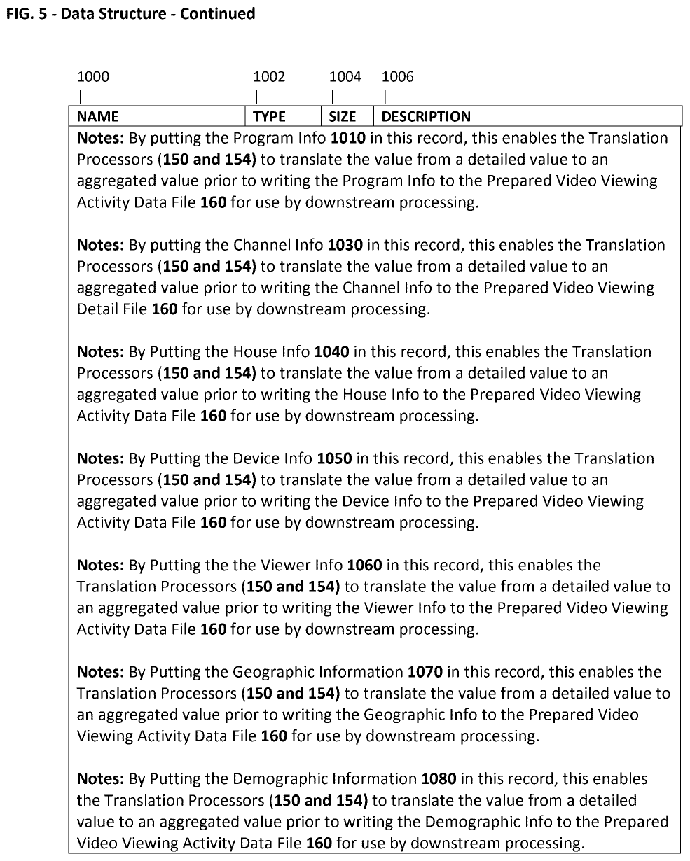

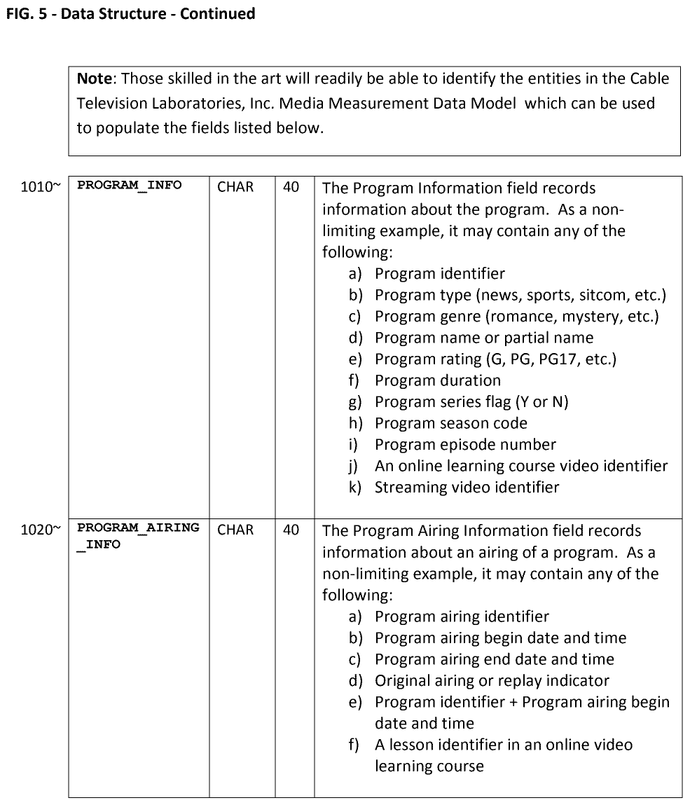

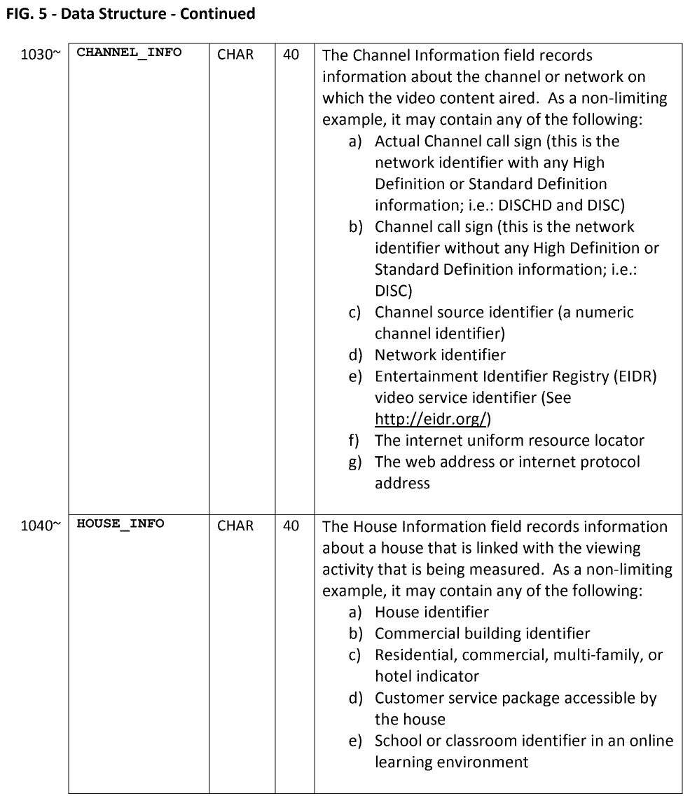

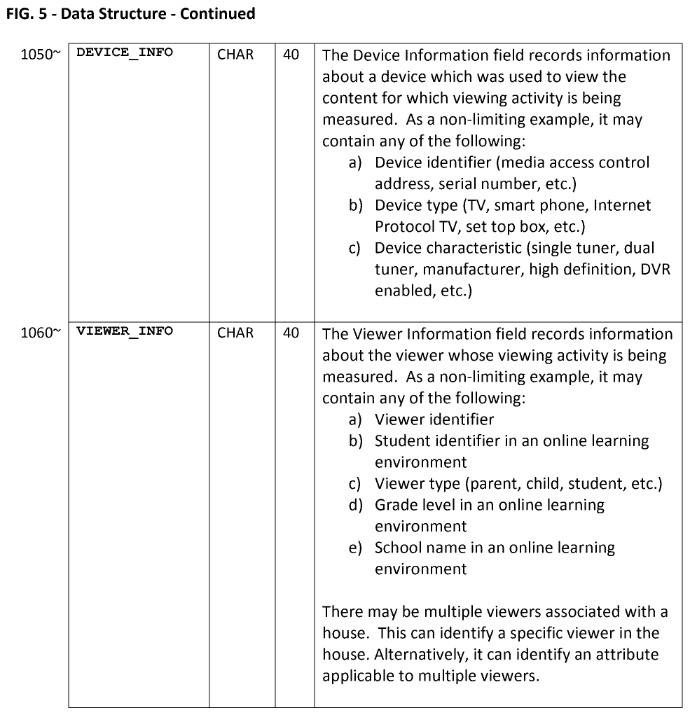

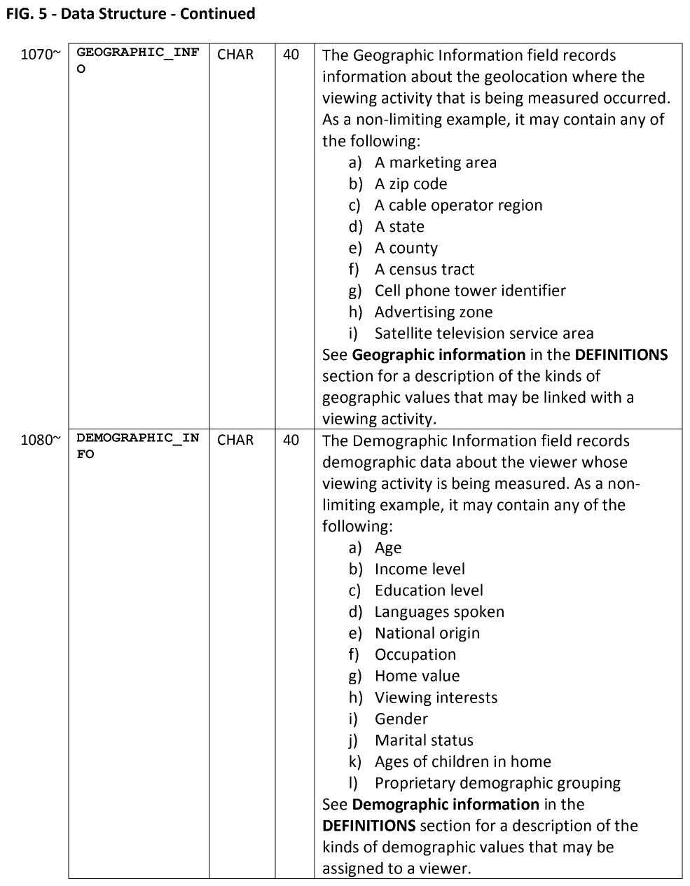

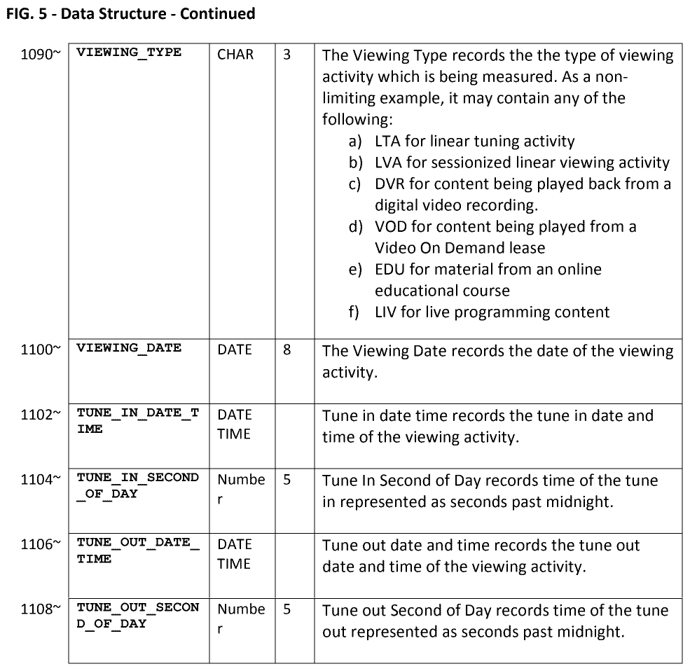

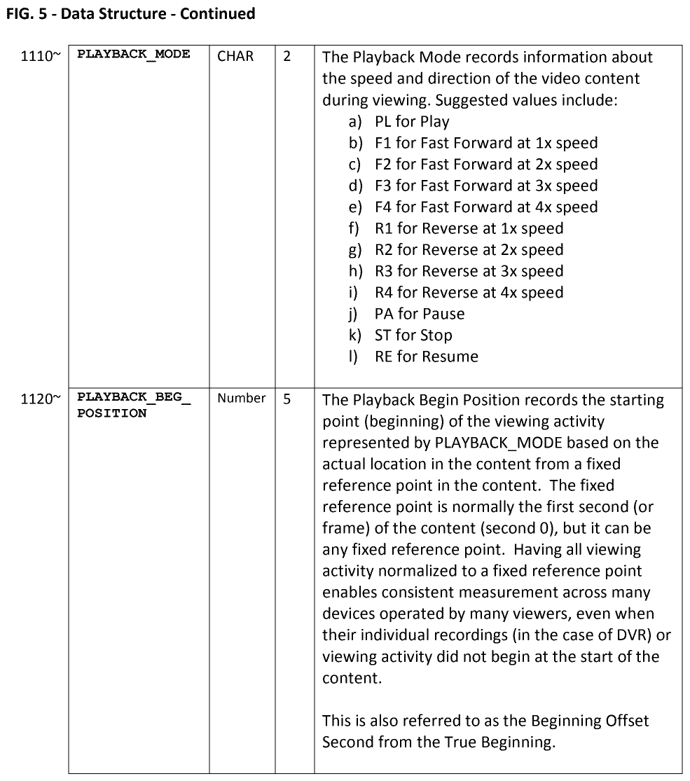

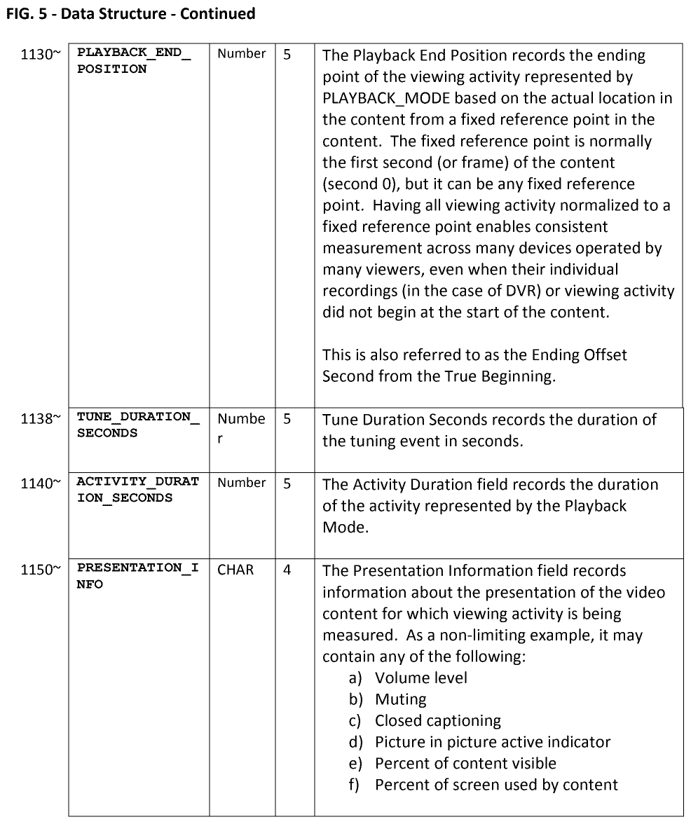

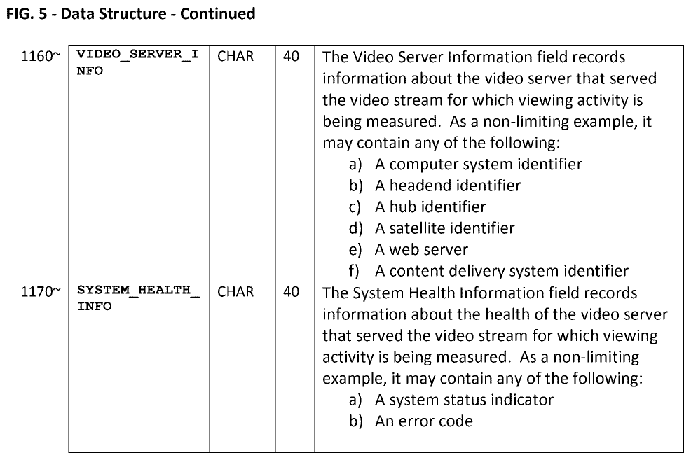

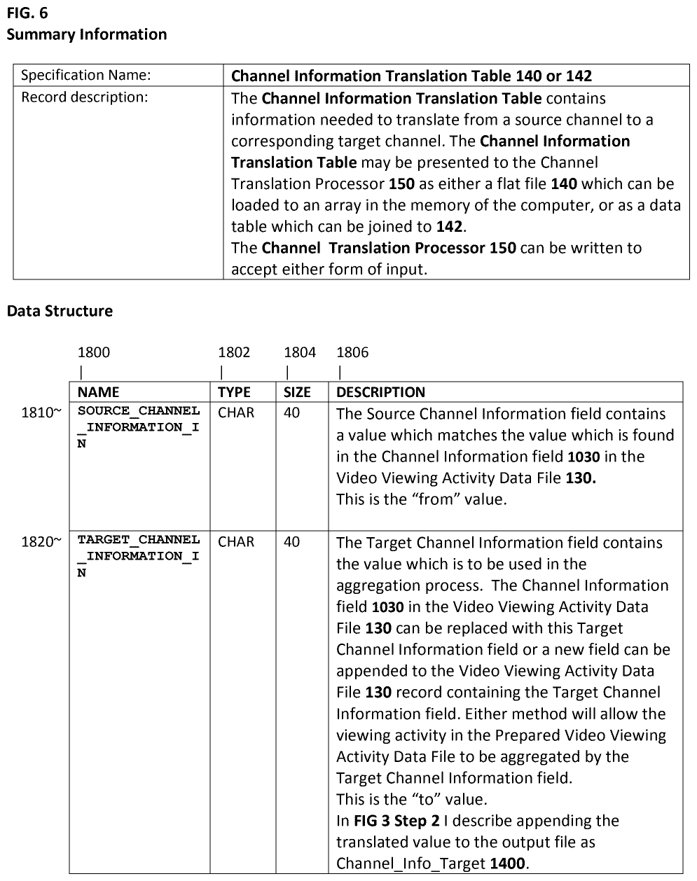

Before resuming the review of FIG. 2, note that the video viewing activity may be sourced from a Media Measurement Database such as the one described in the Cable Television Laboratories, Inc. specification. The populating of the Media Measurement Database 100 is beyond the scope of this application and so only brief remarks will be made in reference to that. There are video viewing data collection systems that are commonly used in the industry for collecting channel tuning or video viewing activity data including switched digital video systems, set top box applications, internet protocol video viewing applications, and other video viewing applications. I have discussed these in detail in my prior applications. These systems enable the collection of the video viewing events which can be loaded to a Media Measurement Database 100. From such a database, Video Viewing Activity Data can be extracted in a format similar to that shown in FIG. 5 Video Viewing Activity Data File 130.

Also before resuming the review of FIG. 2, it is helpful to recognize that creating the Video Viewing Activity Data file is often a time consuming operation. It can be one of the slower tasks in the entire chain of events in analyzing the video viewing activity. For this reason, it is helpful to avoid multiple or repeated data extraction processes. One solution to this problem is to extract a single file which contains all of the video viewing activity in a detailed format (with numerous fields), perhaps on a daily basis for the previous day's viewing activity, and then save that detailed file on a distributed file system. Then that detail file can be used as input to a translation process such as I describe herein where the detailed values are translated to or replaced by summary values as needed to perform the analytical study of interest. By designing the system in this way, the analyst can take advantage of the power of massively parallel systems to create analytical studies very quickly.

Proceeding with the review of FIG. 2, the process begins with Video Viewing Activity File Extract Process Overview 110. The first step is to extract the video viewing events as per Extract Video Viewing Activity Data from Media Measurement Data Base 120. Those skilled in the art will have no difficultly creating a database query or similar process to extract data from a Media Measurement Database 100 or other source and making it available in a format similar to that defined in Video Viewing Activity Data File 130. The file structure is defined in FIG. 5 Video Viewing Activity Data File 130 which describes an exemplary format for the input video viewing activity data.

This data file may contain various types of viewing activity depending on the query defined by the analyst. A non-limiting example of the types are:
a) Linear tuning activity (LTA)
b) Sessionized linear viewing activity (LVA)
c) Digital video recording viewing activity (DVR)
d) Video on demand viewing activity (VOD)
e) Education video viewing activity (EDU)
f) Live viewing activity (LIV).

These are defined next:

Linear tuning activity (LTA)—Linear Tuning Activity is tuning activity which is based on linear tuning events where the viewer tunes to a channel, stays on the channel for some period of time (one second to multiple hours), and then tunes away by tuning to another channel or by initiating some other activity. Linear Tuning Activity may cross program boundaries.

Sessionized linear viewing activity (LVA)—Sessionized linear viewing activity may be derived from linear tuning events or it may be captured by the set top box as sessionized activity. For linear tuning events which fit within program boundaries, the tuning event may be enriched as described in the Cable Television Laboratories, Inc. specification. For linear tuning events which cross program boundaries, the tuning event is divided into shorter duration tuning events as needed to fit within program boundaries as described in the specification; the tuning events are also enriched with additional fields. Because the viewing activity has been transformed to fit within program boundaries, I refer to it as program-based viewing. Linear viewing activity may be extracted from the Cable Television Laboratories, Inc. MMDM or from any source that is able to provide the data in a format suitable for this process.

A non-limiting example will help to explain this:

Device 100 has a linear tuning event consisting of a Tune to ABC at 6:55:00 PM and tune away from ABC at 8:07:59 PM. Assume a program schedule on ABC of News from 6:30:00 PM to 6:59:59 PM, followed by Action Show from 7:00:00 PM to 7:59:59 PM, followed by Sports Show from 8:00:00 PM to 8:29:59 PM. Using this sample data set, we see that the linear tuning event from Device 100 can be sessionized as follows:
i. Session 1: Channel ABC from 6:55:00 PM to 6:59:59 PM tuned to Program ‘News’.
ii. Session 2: Channel ABC from 7:00:00 PM to 7:59:59 PM tuned to Program ‘Action Show’.
iii. Session 3: Channel ABC from 8:00:00 PM to 8:07:59 PM tuned to Program ‘Sports Show.’

This is defined in more detail in the specification that Cable Television Laboratories, Inc. has published as “Audience Data Measurement Specification” referred to previously.

The same video content may air multiple times, so when viewing is being measured it is necessary to track the Program information, Program Airing information, and Channel information along with other fields.

Digital video recording viewing activity (DVR)—DVR viewing activity may be extracted from the Cable Television Laboratories, Inc. MMDM or from any source that is able to provide the data in a format suitable for this process. As a non-limiting example, a PROGRAM may be a baseball game and a PROGRAM_AIRING may be the initial airing of the game followed by a replay later that day (thus two airings). Because a DVR recording is a recording of a video asset that airs on a certain channel at a certain time, DVR assets are also linked with Channel.

When the viewer records a program, they may record any of several airings. Also the program my air on different channels for the original and the replay. For these reasons, the DVR recording and subsequent playback must identify the Program information, Program Airing information, and Channel information along with other fields.

Video on demand viewing activity (VOD)—VOD viewing activity is extracted from the Cable Television Laboratories, Inc. MMDM or from any source that is able to provide the data in a format suitable for this process. As a non-limiting example, a program may be any VOD asset, a movie, a sporting event, an online class, etc. The concept of a PROGRAM_AIRING does not apply to VOD. As to channel, because a VOD Program airs on the preassigned VOD channel, the channel information is not particularly informative in the context of VOD, so it is ignored for purposes of this Application.

Educational viewing activity (EDU)—EDU viewing activity is similar to VOD viewing in that a pre-recorded program is being viewed. This may be an educational video or any other type of video file. EDU viewing activity is often gathered from a web page that has been instrumented to capture this kind of activity.

Live viewing activity (LIV)—LIV viewing activity is any kind of live streaming video activity. LIV viewing activity is often gathered from a web page or cable TV network or satellite TV network that has been instrumented to capture this kind of activity.

Viewing types LVA, DVR, VOD, and EDU all share the characteristic that for measurement purposes, the measuring activity must be based on position in the content rather than a time element such as UTC time or local time. Measuring viewing activity based on position in the content enables creation of metrics having the same basis across LVA, DVR, VOD, and EDU viewing. Furthermore, when measuring based on position in the content, it is necessary to use a fixed reference point such as the actual start of the content. To illustrate, for a DVR recording, not every viewer will record the content beginning at the start of the program. So using position in the recording for measurement would not yield comparable results. Instead it is required to use a fixed reference point (the start of the content), in the actual content, not the start of the recording, and measure viewing from that fixed reference point. Using a fixed reference point enables consistent measurement regardless of whether the user begins recording at the beginning or some other point in the content. The same concept is applicable to LVA and VOD and EDU viewing. This is why position related fields are included in FIG. 5.

Resuming with the review of FIG. 2, those with ordinary skill in the art will readily recognize how to create the Video Viewing Activity Data File 130 (FIG. 5). Note that there is a single record layout for all the record types. Fields which are not used may be left blank.

Once the Video Viewing Activity Data File 130 has been written to the distributed file system it is ready for use by downstream processes such as my Translation Processors.

Depending on the criteria which the analyst intends to use in aggregating the data, various fields can be omitted from the Video Viewing Activity Data File 130 file because the MapReduce process will not use them. I have included these additional fields to provide a comprehensive picture recognizing that one can always drop the fields that they choose not to use.

FIG. 3 illustrates an exemplary process for enriching the Video Viewing Activity Data File 130 with channel information. I present two alternatives: (a) loading the channel information translation table from a flat file into the memory of the computer running the Channel Translation Processor 150, and (b) performing a join operation using channel information translation data from a database table.

The process begins with Channel Enrichment Process Overview 120.

The Channel Translation Processor 150 requires several steps:

### Step 1:

Load the Channel Information Translation Table as flat file 140 into the memory of the computer in a lookup table. This file can be presented to the Channel Translation Processor 150 as a csv file which is then read and loaded to an array in the memory of the computer. A read loop such as the following can be used to load this table:

```
Move 0 to sub
Execute Read Loop until end of file
Read loop
  Read Channel Information Translation Table as flat file 140
    If end of file
      exit loop
    Else
      Add 1 to sub
      move SOURCE_CHANNEL_INFORMATION_IN 1810
        to CHAN-MAP-CHAN-INFO-SOURCE(sub) 1910
      move TARGET_CHANNEL_INFORMATION_IN 1820
        to CHAN-MAP-CHAN-INFO-TARGET(sub) 1920
    end-if
  end loop
```

### Step 2:

Process the Video Viewing Activity Data File 130 using a read loop as follows:

```
Execute Read Loop until end of file
Read Loop
  Read Video Viewing Activity Data File 130
    If end of file
          exit loop
    Else
```

| | |
|---|---|
| MOVE PROGRAM_INFO | 1010 TO PROGRAM_INFO |

1210

| | |
|---|---|
| MOVE PROGRAM_AIRING_INFO | 1020 TO |

PROGRAM_AIRING_INFO 1220

| | |
|---|---|
| MOVE CHANNEL_INFO | 1030 TO CHANNEL_INFO |

1230

| | |
|---|---|
| MOVE HOUSE_INFO | 1040 TO HOUSE_INFO |

1240

| | |
|---|---|
| MOVE DEVICE_INFO | 1050 TO DEVICE_INFO |

1250

| | |
|---|---|
| MOVE VIEWER_INFO | 1060 TO VIEWER_INFO |

1260

| | |
|---|---|
| MOVE GEOGRAPHIC_INFO | 1070 TO |

GEOGRAPHIC_INFO 1270

| | |
|---|---|
| MOVE DEMOGRAPHIC_INFO | 1080 TO |

DEMOGRAPHIC_INFO 1280

| | |
|---|---|
| MOVE VIEWING_TYPE | 1090 TO VIEWING_TYPE |

1290

| | |
|---|---|
| MOVE VIEWING_DATE | 1100 TO VIEWING_DATE |

```
  1300
      MOVE TUNE_IN_DATE_TIME 1102 TO
    TUNE_IN_DATE_TIME 1302
      MOVE TUNE_IN_SECOND_OF_DAY 1104 TO
  TUNE_IN_SECOND_OF_DAY 1304
      MOVE TUNE_OUT_DATE_TIME 1106 TO
  TUNE_OUT_DATE_TIME 1306
      MOVE TUNE_OUT_SECOND_OF_DAY 1108 TO
  TUNE_OUT_SECOND_OF_DAY 1308
```

| | |
|---|---|
| MOVE PLAYBACK_MODE | 1110 TO |

```
  PLAYBACK_MODE 1310
      MOVE PLAYBACK_BEG_POSITION 1120 TO
  PLAYBACK_BEG_POSITION 1320
      MOVE PLAYBACK_END_POSITION 1130 TO
  PLAYBACK_END_POSITION 1330
        MOVE TUNE_DURATION_SECONDS 1138 TO
TUNE_DURATION_SECONDS 1338
    MOVE ACTIVITY_DURATION_SECONDS 1140
  TOACTIVITY_DURATION_SECONDS 1340
```

| | |
|---|---|
| MOVE PRESENTATION_INFO | 1150 TO |

PRESENTATION_INFO 1350

| | |
|---|---|
| MOVE VIDEO_SERVER_INFO | 1160 TO |

VIDEO_SERVER_INFO 1360

| | |
|---|---|
| MOVE SYSTEM_HEALTH_INFO | 1170 TO |

```
  SYSTEM_HEALTH_INFO 1370
      PERFORM DO_TARGET_CHANNEL_LOOKUP (see below)
      Write Prepared Video Viewing Activity Data File 160
    End loop
DO_TARGET_CHANNEL_LOOKUP.
  MOVE ‘N’ TO TARGET-CHANNEL-FOUND
  MOVE ‘N’ TO EXCEEDED-MAX-ROWS-IN-ARRAY
PERFORM VARYING SUB
  FROM 1 BY 1
  UNTIL TARGET-CHANNEL-FOUND = ‘Y’
  OR EXCEEDED-MAX-ROWS-IN-ARRAY = ‘Y’
  IF CHANNEL_INFO 1030 = CHAN-MAP-CHAN-INFO-SOURCE(sub) 1910
  MOVE CHAN-MAP-CHAN-INFO-TARGET(sub) 1920
    TO CHANNEL INFO TARGET 1400
  MOVE ‘Y’ TO TARGET-CHANNEL-FOUND
  END-IF
  IF SUB > 600
  MOVE ‘Y’ TO EXCEEDED-MAX-ROWS-IN-ARRAY
  END-IF
END-PERFORM
```

### Step 3:

When the Process finishes reading the Video Viewing Activity Data File 130, proceed to Provide File to Downstream Process 210.

### Alternative Embodiment

Instead of using a Lookup table as described above, the Channel Information Translation table may be loaded to a database table. In that case the DO_TARGET_CHANNEL_LOOKUP process is done as follows:

```
SELECT TARGET_CHANNEL_INFORMATION_IN 1820
  INTO CHANNEL_INFO_TARGET 1400
FROM CHANNEL INFORMATION TRANSLATION TABLE 142
  WHERE SOURCE_CHANNEL_INFORMATION_IN 1810 =
CHANNEL_INFO 1030
```

This completes FIG. 3.

FIG. 4 illustrates an exemplary process for enriching the Video Viewing Activity Data File 130 with any variety of translation data. Whereas FIG. 3 was focused on translating Channel Information, FIG. 4 presents a more generalized solution which enables the analyst to translate, as a Non-limiting example, any of the following fields:
(i) program information,
(ii) channel information,
(iii) house information,
(iv) device information,
(v) viewer information,
(vi) geographic information,
(vii) demographic information.

I present two alternatives: (a) loading the data translation table from a flat file into the memory of the computer running the Data Translation Processor 154, and (b) performing a join operation using data translation data from a database table.

The process begins with Generalized Enrichment Process Overview 124.

The Data Translation Processor 154 requires several steps:

### Step 1:

Load the Data Translation Table as flat file 146 into the memory of the computer in a lookup table. This file can be presented to the Data Translation Processor 154 as a csv file which is then read and loaded to an array in the memory of the computer.

A read loop such as the following can be used to load this table:

```
Move 0 to sub
Execute Read Loop until end of file
Read loop
  Read Data Translation Table as flat file 146
  If end of file
    exit loop
  Else
    Add 1 to sub
    move TRANSLATION_VALUE_TYPE-IN 2005
            to TRANSLATION_VALUE_TYPE(sub)
        2105
    move SOURCE_TRANSLATION_VALUE-IN 2010
            to SOURCE_TRANSLATION_VALUE(sub)
        2110
    move TARGET_TRANSLATION_VALUE-IN 2020
            to TARGET_TRANSLATION_VALUE(sub)
        2120
    end-if
  end loop
```

### Step 2:

Accept the various input parameters which will indicate which translations are being done. There is one parameter for each kind of translation which may be done. Each parameter contains a value of ‘Y’ or ‘N’ indicating whether or not that field will be translated by the Data Translation Processor 154. The code is as follows:

```
Accept program-information-translation-flag from
  job-run-parm-program-information
Accept channel-information-translation-flag from
  job-run-parm-channel-information
Accept house-information-translation-flag from
  job-run-parm-house-information
Accept device-information-translation-flag from
  job-run-parm-device-information
Accept viewer-information-translation-flag from
  job-run-parm-viewer-information
Accept geographic-information-translation-flag from
  job-run-parm-geographic-information
Accept demographic-information-translation-flag from
  job-run-parm-demographic-information
  Step 3:
Process the Video Viewing Activity Data File 130 using a read loop as follows:
Execute Read Loop until end of file
Read Loop
  Read Video Viewing Activity Data File 130
    If end of file
      exit loop
    Else
      IF program-information-translation-flag = ‘Y’
          PERFORM DO TARGET PROGRAM LOOKUP (see below)
      ELSE
          MOVE PROGRAM_INFO 1010 TO PROGRAM_INFO
1210
      END-IF
            MOVE PROGRAM AIRING INFO 1020 TO
PROGRAM_AIRING_INFO 1220
          IF channel-information-translation-flag = ‘Y’
              PERFORM DO TARGET CHANNEL LOOKUP (see below)
          ELSE
              MOVE CHANNEL_INFO 1030 TO CHANNEL_INFO
1230
          END-IF
        IF house-information-translation-flag = ‘Y’
          PERFORM DO TARGET HOUSE LOOKUP (see below)
        ELSE
            MOVE HOUSE_INFO 1040 TO HOUSE_INFO
1240
        END-IF
        IF device-information-translation-flag = ‘Y’
          PERFORM DO TARGET DEVICE LOOKUP (see below)
        ELSE
            MOVE DEVICE_INFO 1050 TO DEVICE_INFO
1250
        END-IF
        IF viewer-information-translation-flag = ‘Y’
          PERFORM DO TARGET VIEWER LOOKUP (see below)
        ELSE
          MOVE VIEWER_INFO 1060 TO VIEWER_INFO
1260
        END-IF
        IF geographic-information-translation-flag = ‘Y’
          PERFORM DO TARGET GEOGRAPHIC LOOKUP (see below)
        ELSE
          MOVE GEOGRAPHIC_INFO 1070 TO
  GEOGRAPHIC_INFO 1270
        END_IF
        IF demographic-information-translation-flag = ‘Y’
          PERFORM DO TARGET DEMOGRAPHIC LOOKUP (see below)
        ELSE
          MOVE DEMOGRAPHIC_INFO 1080 TO DEMOGRAPHIC
INFO 1280
        END-IF
        MOVE VIEWING_TYPE 1090 TO VIEWING_TYPE
            1290
        MOVE VIEWING_DATE 1100 TO VIEWING_DATE
            1300
        MOVE TUNE_IN_DATE_TIME 1102 TO
  TUNE_IN_DATE_TIME 1302
        MOVE TUNE_IN_SECOND_OF_DAY 1104 TO
  TUNE_IN_SECOND_OF_DAY 1304
        MOVE TUNE_OUT_DATE_TIME 1106  TO
  TUNE_OUT_DATE_TIME 1306
        MOVE TUNE_OUT_SECOND_OF_DAY 1108 TO
TUNE_OUT_SECOND_OF_DAY 1308
        MOVE PLAYBACK_MODE 1110 TO PLAYBACK_MODE
            1310
        MOVE PLAYBACK_BEG_POSITION 1120 TO
  PLAYBACK_BEG_POSITION 1320
        MOVE PLAYBACK_END_POSITION 1130 TO
  PLAYBACK_END_POSITION 1330
        MOVE TUNE_DURATION_SECONDS 1138 TO
  TUNE_DURATION_SECONDS 1338
      MOVE ACTIVITY_DURATION_SECONDS 1140 TO
  ACTIVITY_DURATION_SECONDS 1340
        MOVE PRESENTATION_INFO 1150 TO
  PRESENTATION_INFO 1350
        MOVE VIDEO_SERVER_INFO 1160 TO
  VIDEO_SERVER_INFO 1360
        MOVE SYSTEM_HEALTH_INFO 1170 TO
  SYSTEM_HEALTH_INFO 1370
        Write Prepared Video Viewing Activity Data File 160
        End-if
  End loop
DO_TARGET_PROGRAM_LOOKUP.
  MOVE ‘N’ TO TARGET-PROGRAM-FOUND
  MOVE ‘N’ TO EXCEEDED-MAX-ROWS-IN-ARRAY
PERFORM VARYING SUB
  FROM 1BY 1
  UNTIL TARGET-PROGRAM-FOUND = ‘Y’
    OR EXCEEDED-MAX-ROWS-IN-ARRAY = ‘Y’
    IF TRANSLATION_VALUE_TYPE (sub) 2105 = 'PROGRAM'
        IF PROGRAM_INFO 1010 = SOURCE_TRANSLATION_VALUE (sub)
  2110
          MOVE TARGET_TRANSLATION_VALUE (sub) 2120
            TO PROGRAM INFO 1210
          MOVE ‘Y’ TO TARGET-PROGRAM-FOUND
        END-IF
      END-IF
      IF SUB > 1000
        MOVE ‘Y’ TO EXCEEDED-MAX-ROWS-IN-ARRAY
        MOVE ‘not available’ TO PROGRAM INFO 1210
      END-IF
END-PERFORM
Alternative Embodiment
```

Instead of using a Lookup table as described above, the Data Translation Table may be provided as a database table as shown by Data Translation Table as database Table 148. In that case the DO_TARGET_PROGRAM_LOOKUP process is done as follows:

```
      SELECT TARGET_TRANSLATION_VALUE-IN 2020
          INTO PROGRAM_INFO 1210
          FROM DATA TRANSLATION TABLE 148
            WHERE TRANSLATION_VALUE_TYPE-IN 2005 = ‘PROGRAM’
            AND SOURCE_TRANSLATION_VALUE-IN 2010 = PROGRAM_INFO
          1010
DO_TARGET_CHANNEL_LOOKUP.
MOVE ‘N’ TO TARGET-CHANNEL-FOUND
MOVE ‘N’ TO EXCEEDED-MAX-ROWS-IN-ARRAY
PERFORM VARYING SUB
  FROM 1 BY 1
  UNTIL TARGET-CHANNEL-FOUND = ‘Y’
      OR EXCEEDED-MAX-ROWS-IN-ARRAY = ‘Y’
      IF TRANSLATION_VALUE_TYPE(sub) 2105 = ‘CHANNEL’
        IF CHANNEL_INFO 1030 = SOURCE_TRANSLATION_VALUE(sub) 2110
        MOVE TARGET_TRANSLATION_VALUE(sub) 2120 TO CHANNEL_INFO
1230
        MOVE ‘Y’ TO TARGET-CHANNEL-FOUND
      END-IF
    END-IF
    IF SUB > 1000
      MOVE ‘Y’ TO EXCEEDED-MAX-ROWS-IN-ARRAY
      MOVE ‘not available’ TO CHANNEL_INFO 1230
    END-IF
END-PERFORM
```

### Alternative Embodiment

Instead of using a Lookup table as described above, the Data Translation Table may be provided as a database table as shown by Data Translation Table as database Table 148. In that case the DO_TARGET_CHANNEL_LOOKUP process is done as follows:

```
    SELECT TARGET_TRANSLATION_VALUE-IN 2020
        INTO CHANNEL_INFO 1230
      FROM DATA TRANSLATION TABLE 148
        WHERE TRANSLATION_VALUE_TYPE-IN 2005 = ‘CHANNEL’
        AND SOURCE_TRANSLATION_VALUE-IN 2010 = CHANNEL_INFO
        1030
DO_TARGET_HOUSE_LOOKUP.
  MOVE ‘N’ TO TARGET-HOUSE-FOUND
  MOVE ‘N’ TO EXCEEDED-MAX-ROWS-IN-ARRAY
  PERFORM VARYING SUB
    FROM 1 BY 1
    UNTIL TARGET-HOUSE-FOUND = ‘Y’
      OR EXCEEDED-MAX-ROWS-IN-ARRAY = ‘Y’
      IF TRANSLATION_VALUE_TYPE (sub) 2105 = ‘HOUSE’
        IF HOUSE_INFO 1040 = SOURCE_TRANSLATION_VALUE (sub) 2110
          MOVE TARGET_TRANSLATION_VALUE(sub) 2120 TO
  HOUSE_INFO 1240
          MOVE ‘Y’ TO TARGET-HOUSE-FOUND
        END-IF
      END-IF
      IF SUB > 1000
        MOVE ‘Y’ TO EXCEEDED-MAX-ROWS-IN-ARRAY
        MOVE ‘not available’ TO HOUSE INFO 1240
      END-IF
    END-PERFORM
```

### Alternative Embodiment

Instead of using a Lookup table as described above, the Data Translation Table may be provided as a database table as shown by Data Translation Table as database Table 148. In that case the DO_TARGET_HOUSE_LOOKUP process is done as follows:

```
  SELECT TARGET_TRANSLATION_VALUE-IN 2020
      INTO HOUSE_INFO 1240
  FROM DATA TRANSLATION TABLE 148
      WHERE TRANSLATION_VALUE_TYPE-IN 2005 = ‘HOUSE’
AND SOURCE_TRANSLATION_VALUE-IN 2010 = HOUSE INFO 1040
DO_TARGET_DEVICE_LOOKUP.
MOVE ‘N’ TO TARGET-DEVICE-FOUND
MOVE ‘N’ TO EXCEEDED-MAX-ROWS-IN-ARRAY
PERFORM VARYING SUB
  FROM 1 BY 1
  UNTIL TARGET-DEVICE-FOUND = ‘Y’
    OR EXCEEDED-MAX-ROWS-IN-ARRAY = ‘Y’
    IF TRANSLATION_VALUE_TYPE(sub) 2105 = ‘DEVICE’
      IF DEVICE_INFO 1050 = SOURCE_TRANSLATION_VALUE(sub) 2110
        MOVE TARGET_TRANSLATION_VALUE(sub) 2120 TO
DEVICE_INFO 1250
        MOVE ‘Y’ TO TARGET-DEVICE-FOUND
      END-IF
    END-IF
    IF SUB > 1000
      MOVE ‘Y’ TO EXCEEDED-MAX-ROWS-IN-ARRAY
      MOVE ‘not available’ TO DEVICE_INFO 1250
    END-IF
  END-PERFORM
```

### Alternative Embodiment

Instead of using a Lookup table as described above, the Data Translation Table may be provided as a database table as shown by Data Translation Table as database Table 148. In that case the DO_TARGET_DEVICE_LOOKUP process is done as follows:

```
  SELECT TARGET_TRANSLATION_VALUE-IN 2020
      INTO DEVICE_INFO 1250
    FROM DATA TRANSLATION TABLE 148
      WHERE TRANSLATION_VALUE_TYPE-IN 2005 = ‘DEVICE’
      AND SOURCE_TRANSLATION_VALUE-IN 2010 = DEVICE_INFO 1050
DO_TARGET_VIEWER_LOOKUP.
MOVE ‘N’ TO TARGET-VIEWER-FOUND
MOVE ‘N’ TO EXCEEDED-MAX-ROWS-IN-ARRAY
PERFORM VARYING SUB
  FROM 1 BY 1
  UNTIL TARGET-VIEWER-FOUND = ‘Y’
      OR EXCEEDED-MAX-ROWS-IN-ARRAY = ‘Y’
      IF TRANSLATION_VALUE_TYPE (sub) 2105 = ‘VIEWER’
        IF VIEWER_INFO 1060 = SOURCE_TRANSLATION_VALUE (sub) 2110
          MOVE TARGET_TRANSLATION_VALUE (sub) 2120 TO VIEWER_INFO
      1260
          MOVE ‘Y’ TO TARGET-VIEWER-FOUND
        END-IF
      END-IF
      IF SUB > 1000
        MOVE ‘Y’ TO EXCEEDED-MAX-ROWS-IN-ARRAY
        MOVE ‘not available’ TO VIEWER_INFO 1260
      END-IF
    END-PERFORM
```

### Alternative Embodiment

Instead of using a Lookup table as described above, the Data Translation Table may be provided as a database table as shown by Data Translation Table as database Table 148. In that case the DO_TARGET_VIEWER_LOOKUP process is done as follows:

```
  SELECT TARGET TRANSLATION VALUE-IN 2020
      INTO VIEWER_INFO 1260
    FROM DATA TRANSLATION TABLE 148
      WHERE TRANSLATION VALUE TYPE-IN 2005 = ‘VIEWER’
      AND SOURCE TRANSLATION VALUE-IN 2010 = VIEWER_INFO 1060
DO_TARGET_GEOGRAPHIC_LOOKUP.
MOVE ‘N’ TO TARGET-GEOGRAPHIC-FOUND
MOVE ‘N’ TO EXCEEDED-MAX-ROWS-IN-ARRAY
PERFORM VARYING SUB
  FROM 1 BY 1
  UNTIL TARGET-GEOGRAPHIC-FOUND = ‘Y’
      OR EXCEEDED-MAX-ROWS-IN-ARRAY = ‘Y’
      IF TRANSLATION_VALUE_TYPE(sub) 2105 = ‘GEOGRAPHIC’
      IF GEOGRAPHIC_INFO 1070 = SOURCE_TRANSLATION_VALUE (sub) 2110
        MOVE TARGET_TRANSLATION_VALUE (sub) 2120 TO GEOGRAPHIC
INFO 1270
        MOVE ‘Y’ TO TARGET-GEOGRAPHIC-FOUND
      END-IF
    END-IF
    IF SUB > 1000
      MOVE ‘Y’ TO EXCEEDED-MAX-ROWS-IN-ARRAY
      MOVE ‘not available’ TO GEOGRAPHIC_INFO 1270
    END-IF
END-PERFORM
```

### Alternative Embodiment

Instead of using a Lookup table as described above, the Data Translation Table may be provided as a database table as shown by Data Translation Table as database Table 148. In that case the DO_TARGET_GEOGRAPHIC_LOOKUP process is done as follows:

```
  SELECT TARGET_TRANSLATION_VALUE-IN 2020
      INTO GEOGRAPHIC_INFO 1270
  FROM DATA TRANSLATION TABLE 148
      WHERE TRANSLATION_VALUE_TYPE-IN 2005 = ‘GEOGRAPHIC’
      AND SOURCE_TRANSLATION_VALUE-IN 2010 = GEOGRAPHIC_INFO
      1070
DO_TARGET_DEMOGRAPHIC_LOOKUP.
MOVE ‘N’ TO TARGET-DEMOGRAPHIC-FOUND
MOVE ‘N’ TO EXCEEDED-MAX-ROWS-IN-ARRAY
PERFORM VARYING SUB
  FROM 1 BY 1
  UNTIL TARGET-DEMOGRAPHIC-FOUND = ‘Y’
      OR EXCEEDED-MAX-ROWS-IN-ARRAY = ‘Y’
      IF TRANSLATION_VALUE_TYPE (sub) 2105 = ‘DEMOGRAPHIC’
        IF DEMOGRAPHIC_INFO 1080 = SOURCE_TRANSLATION_VALUE(sub)
2110
          MOVE TARGET_TRANSLATION_VALUE (sub) 2120 TO
          DEMOGRAPHIC_INFO 1280 MOVE ‘Y’ TO TARGET-DEMOGRAPHIC-
          FOUND
        END-IF
      END-IF
      IF SUB > 1000
        MOVE ‘Y’ TO EXCEEDED-MAX-ROWS-IN-ARRAY
        MOVE ‘not available’ TO DEMOGRAPHIC_INFO 1280
      END-IF
    END-PERFORM
```

### Alternative Embodiment

Instead of using a Lookup table as described above, the Data Translation Table may be provided as a database table as shown by Data Translation Table as database Table 148. In that case the DO_TARGET_DEMOGRAPHIC_LOOKUP process is done as follows:

```
SELECT TARGET_TRANSLATION_VALUE-IN 2020
  INTO DEMOGRAPHIC_INFO 1280
FROM DATA TRANSLATION TABLE 148
  WHERE TRANSLATION_VALUE_TYPE-IN 2005 = ‘DEMOGRAPHIC’
  AND SOURCE_TRANSLATION_VALUE-IN 2010 = DEMOGRAPHIC_INFO
  1080
```

### Step 4:

When the Data Translation Processor 154 finishes reading the Video Viewing Activity Data File 130 and enriching each record as needed, proceed to Provide File to Downstream Processes 214.

Note: In each case the Prepared Video Viewing Activity Data File 160 records can be written directly to a distributed file system such as, but not limited to, the Hadoop Distributed File System (HDFS) so that the prepared video viewing activity records are ready for use by downstream processes.

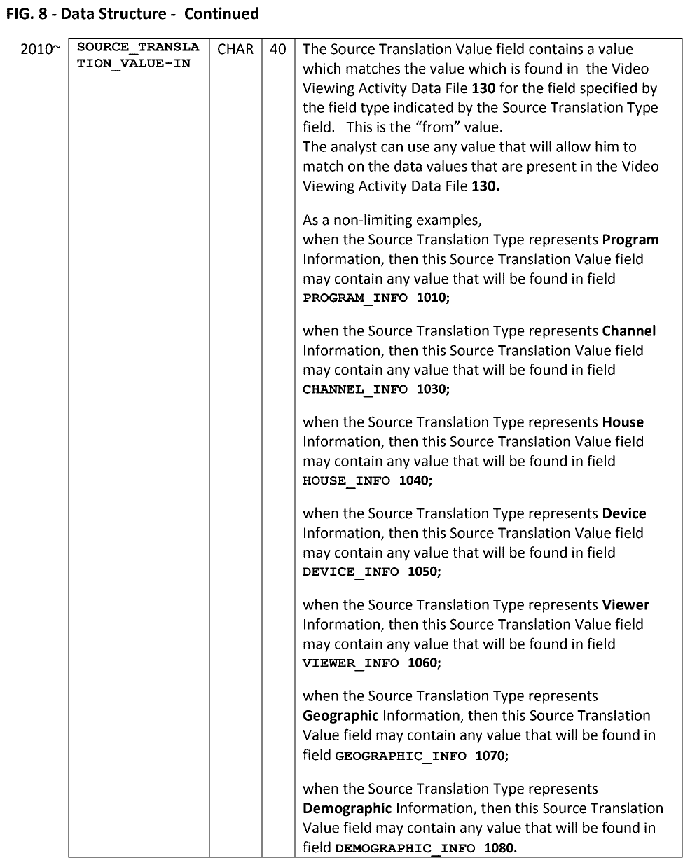

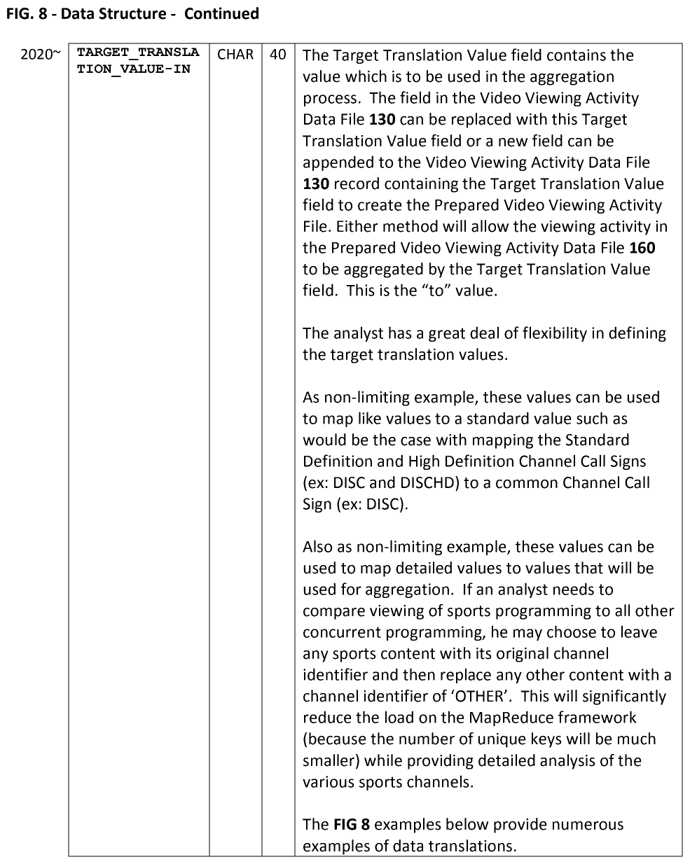

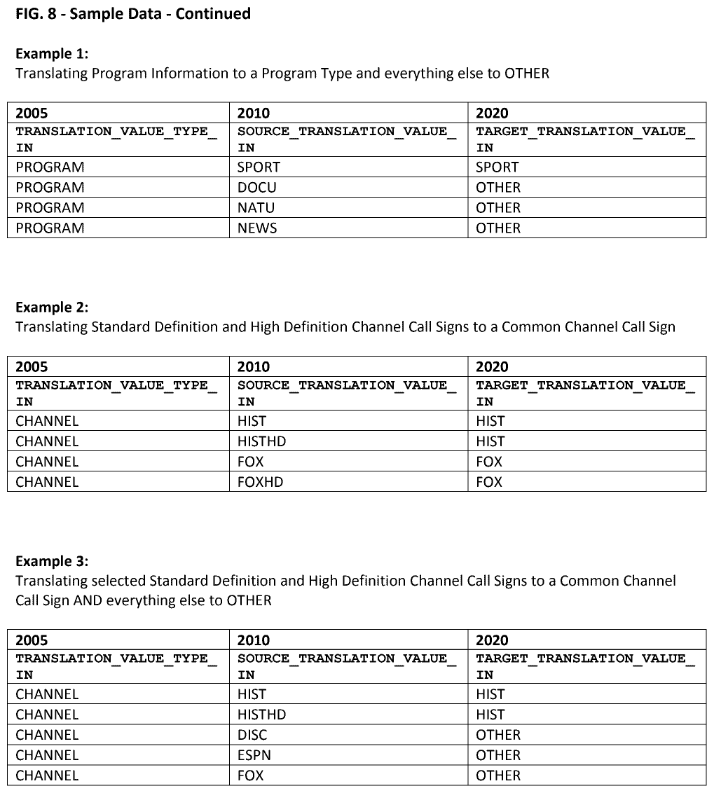

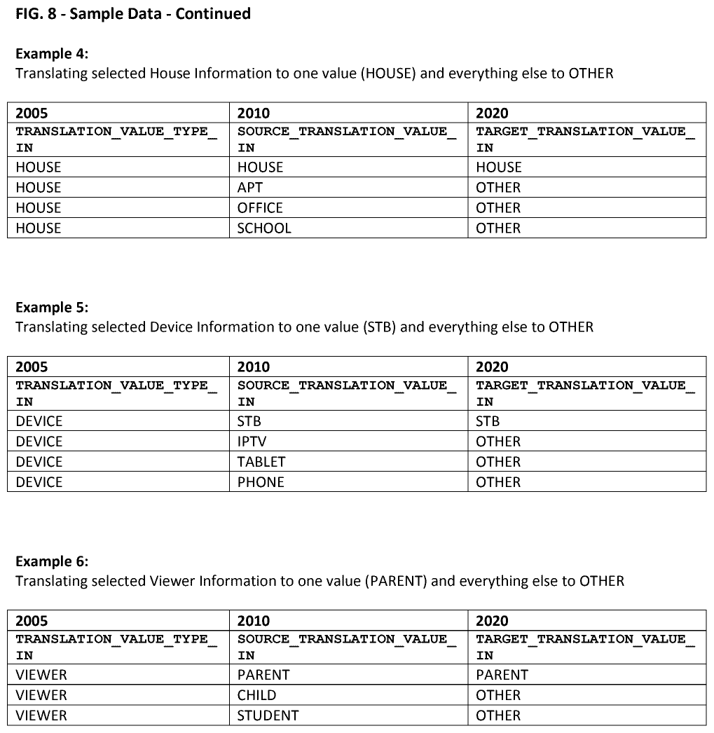

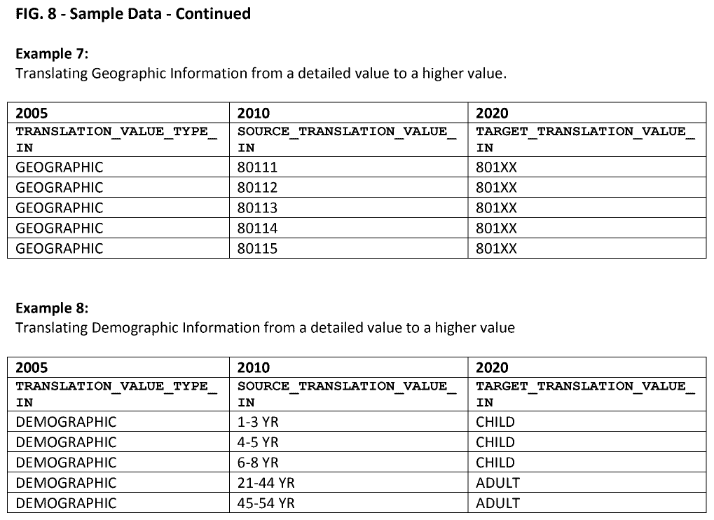

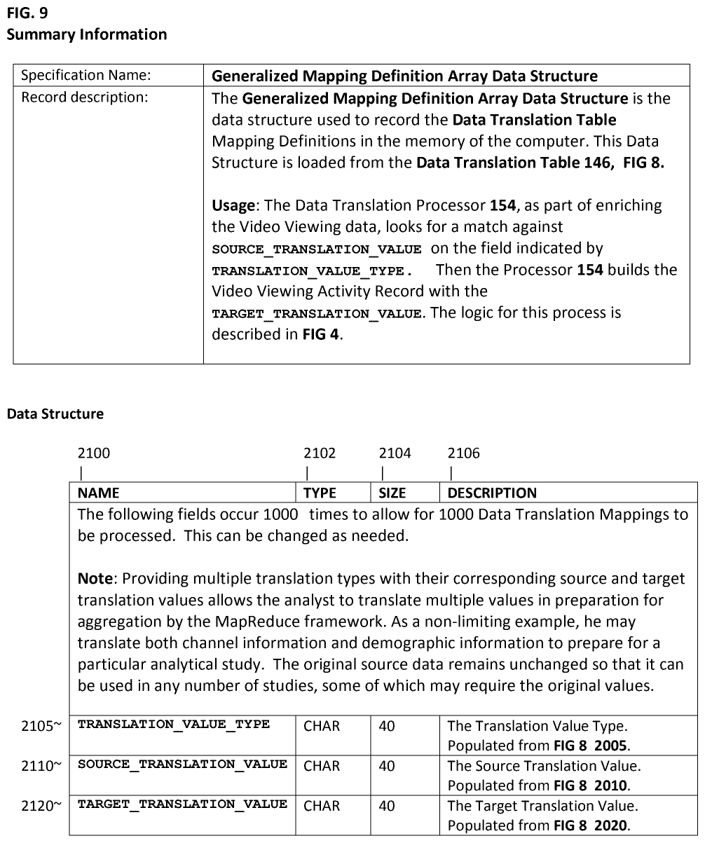

For each of these embodiments, at the completion of Data Translation Processor 154, one record has been written to the Prepared Video Viewing Activity Data File 160 for each record in the input file. In FIG. 8 below I will review various Before and After images to provide examples of inputs and subsequent outputs from the Data Translation Processor 154.

Those skilled in the art will readily recognize that the Data Translation Processor 154 is suitable for running in parallel on multiple computers simultaneously with each process creating Prepared Video Viewing Activity Data File records that can be fed into the downstream processes.

Note: The Video Viewing Activity Data File 130 can be provided to the Data Translation Processor 154 process in any computer readable format including, but not limited to, database tables, flat files, JSON messages, and XML messages. Alternatively, such video viewing events can be collected directly from the source without the need for a Media Measurement Database 100. In such a case, those events can still be provided as video viewing activity in a format similar to that shown in FIG. 5 for use by the Data Translation Processor 154.

This concludes discussion on FIG. 4.

FIG. 5 illustrates an exemplary record layout for a Video Viewing Activity Data File 130 record formatted for use as input to either the Channel Translation Processor 150 or the Data Translation Processor 154, according to one embodiment. There is Summary Information followed by the Data Structure including field definitions.

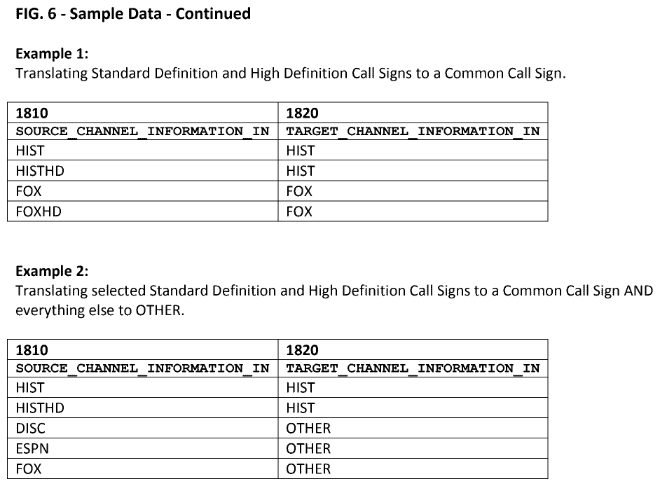

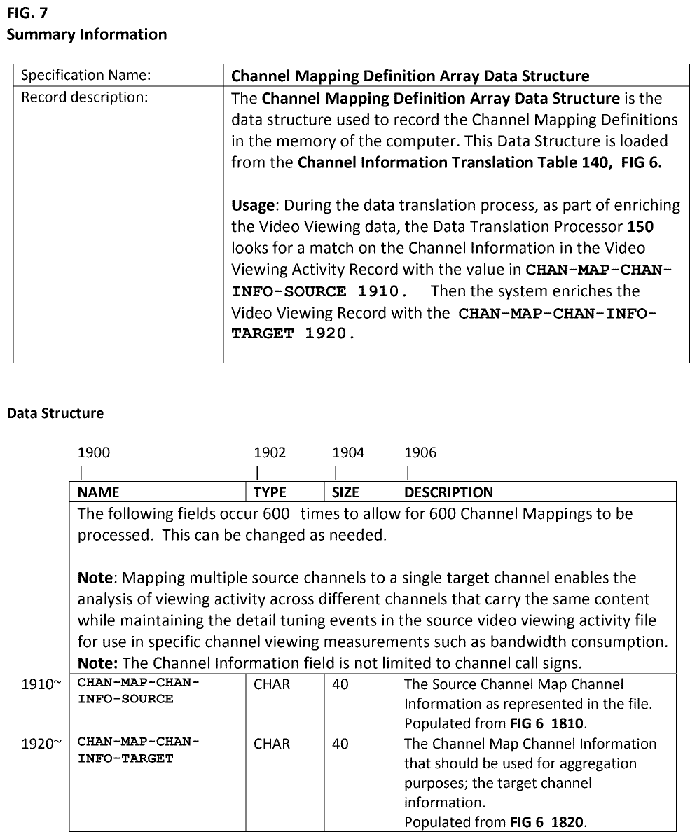

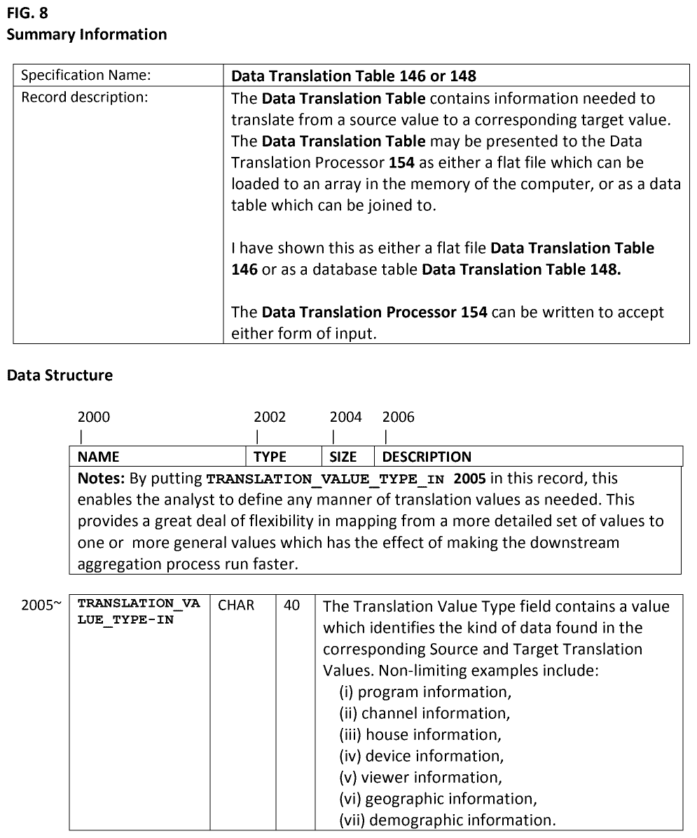

FIG. 6 illustrates an exemplary record layout for a Channel Information Translation Table 140 or 142 record formatted for use as input to the Channel Translation Processor 150, according to one embodiment. There is Summary Information followed by the Data Structure including field definitions. After the Data Structure there is a set of Sample Data.

FIG. 6 Example 1 shows an example of the data that would be used to translate Standard Definition and High Definition Call Signs to the corresponding Common Call Sign, according to one embodiment. This kind of translation can be used in relation to audience viewership measurement where it is desirable to combine the viewing of standard definition and high definition channels into a single call sign for the applicable channel.

FIG. 6 Example 2 shows an example of the data that would be used to translate selected Standard Definition and High Definition Call Signs to a Common Call Sign, and then translate all the other channel call signs to a common value, according to one embodiment. This kind of translation can be used in relation to audience viewership measurement where it is desirable to combine the viewing of standard definition and high definition channels into a single call sign for the applicable channel with the objective of simply measuring viewing of that specific channel, either by itself or as a percentage of the overall viewing that is occurring during the measurement window. By reducing the number of target channels to a single value for all of the channels that are not of interest in the analysis, the aggregation run time can be reduced substantially and the computer resource usage can be reduced as well.

Those skilled in the art will be able to create various combinations of the mappings to meet any number of analytical needs.

FIG. 7 illustrates an exemplary data structure for a Channel Mapping Definition Array Data Structure which may be used by the Channel Translation Processor 150, according to one embodiment. There is Summary Information followed by the Data Structure including field definitions.

The process for loading the file in FIG. 6 to the Array in FIG. 7 is described in FIG. 3 Step 1.

FIG. 8 illustrates an exemplary record layout for a Data Translation Table 146 or 148 record formatted for use as input to the Data Translation Processor 154, according to one embodiment. There is Summary Information followed by the Data Structure including field definitions. After the Data Structure there is a set of Sample Data.

FIG. 8 Example 1 relates to translating PROGRAM information, according to one embodiment. This figure shows an example of the data that would be used to translate program type. This non-limiting example shows keeping the type of “SPORT” unchanged while replacing the other values with a value of “OTHER”. This kind of translation can be used in relation to audience viewership measurement where the analyst needs to compare viewing of one kind of program with all the other viewing that is happening concurrently.

FIG. 8 Example 2 shows an example of the data that would be used to translate Standard Definition and High Definition Call Signs to a Common Call Sign, according to one embodiment. This kind of translation can be used in relation to audience viewership measurement where it is desirable to combine the viewing of standard definition and high definition channels into a single call sign for the applicable channel.

FIG. 8 Example 3 shows an example of the data that would be used to translate selected Standard Definition and High Definition Call Signs to a Common Call Sign, and then translate all the other channel call signs to a common value, according to one embodiment. This kind of translation can be used in relation to audience viewership measurement where it is desirable to combine the viewing of standard definition and high definition channels into a single call sign for the applicable channel with the objective of simply measuring that specific channel. By reducing the number of target channels to a single value for all of the channels that are not of interest in the analysis, the aggregation run time can be reduced substantially and the computer resources can be reduced as well.

FIG. 8 Example 4 relates to translating HOUSE information, according to one embodiment. This figure shows an example of the data that would be used to translate house type. This non-limiting example shows keeping the type of “HOUSE” unchanged while replacing the other values (APT, OFFICE, SCHOOL) with a value of “OTHER”. This kind of translation can be used in relation to audience viewership measurement where the analyst needs to compare viewing of one kind of house with all the other viewing that is happening concurrently (HOUSE viewing vs. combined viewing by APT, OFFICE, and SCHOOL).

FIG. 8 Example 5 relates to translating DEVICE information, according to one embodiment. This figure shows an example of the data that would be used to translate device type. This non-limiting example shows keeping the type of “STB” unchanged while replacing the other values (IPTV, TABLET, PHONE) with a value of “OTHER”. This kind of translation can be used in relation to audience viewership measurement where the analyst needs to compare viewing of one kind of device with all the other viewing that is happening concurrently (STB viewing vs. combined viewing by IPTV, TABLET, and PHONE).

FIG. 8 Example 6 relates to translating VIEWER information, according to one embodiment. This figure shows an example of the data that would be used to translate viewer type. This non-limiting example shows keeping the type of “PARENT” unchanged while replacing the other values (CHILD, STUDENT) with a value of “OTHER”. This kind of translation can be used in relation to audience viewership measurement where the analyst needs to compare viewing of one kind of viewer with all the other viewing that is happening concurrently (PARENT viewing vs. combined viewing by CHILD and STUDENT).

FIG. 8 Example 7 relates to translating GEOGRAPHIC information, according to one embodiment. This figure shows an example of the data that would be used to translate geographic information. This non-limiting example shows translating from a more detailed view to a higher view. Thus each of the detailed zip codes values is replaced by a value with only the first three digits of the zip code followed by XX. This kind of translation can be used in relation to audience viewership measurement where the analyst needs to aggregated the viewing of the individual zip codes to a higher level code.

FIG. 8 Example 8 relates to translating DEMOGRAPHIC information, according to one embodiment. This figure shows an example of the data that would be used to translate demographic information. This non-limiting example shows translating from a more detailed view which lists age ranges of children and adults to a higher view which simply lists CHILD and ADULT. Thus each of the detailed age range values for children is replaced by the value “CHILD” and the adult age ranges are replaced by “ADULT”. This kind of translation can be used in relation to audience viewership measurement where the analyst needs to aggregate the viewing of the various age ranges to a more general value.

### FIG. 8 Summary

Each of the above non-limiting examples shows translating a more detailed value to a less detailed value. By reducing the number of distinct values to be used in the aggregation process, the aggregation run time can be reduced substantially and the computer resource usage can be reduced as well.

Those skilled in the art will be able to create various combinations of the mappings to meet any number of analytical needs.

FIG. 9 illustrates an exemplary data structure for a Generalized Mapping Definition Array Data Structure which may be used by the Data Translation Processor 154, according to one embodiment. There is Summary Information followed by the Data Structure including field definitions.

The process for loading the file in FIG. 8 to the Array in FIG. 9 is described in FIG. 4 Step 1.

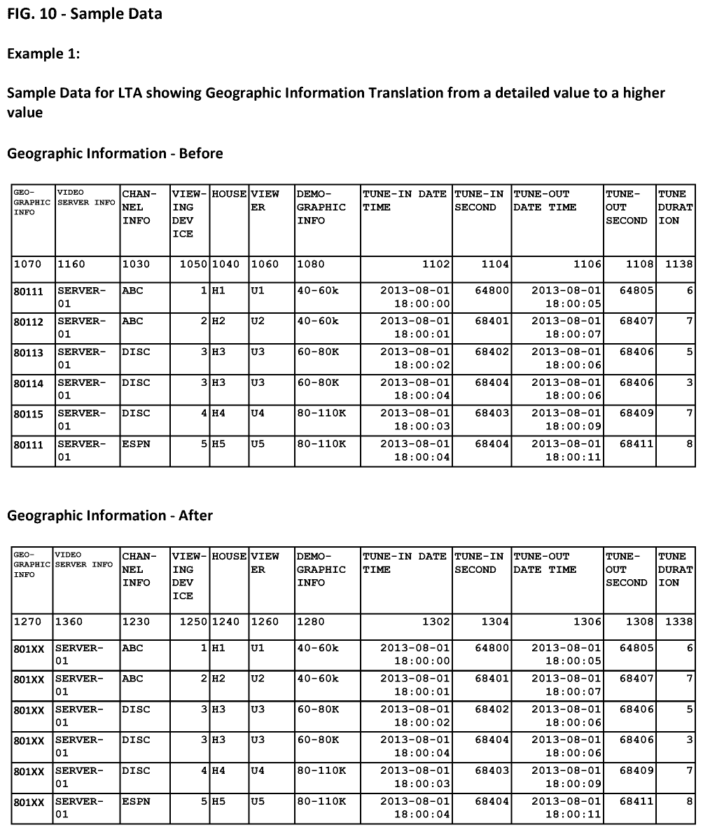

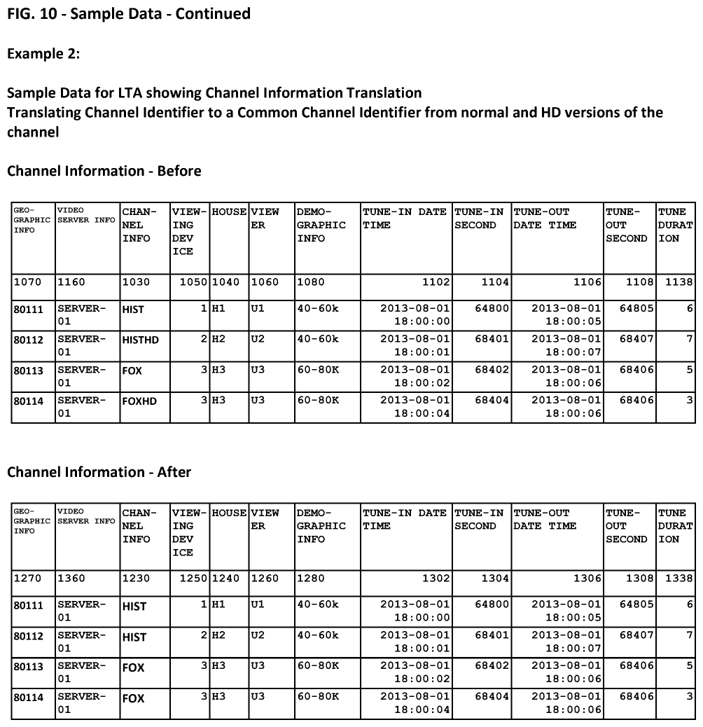

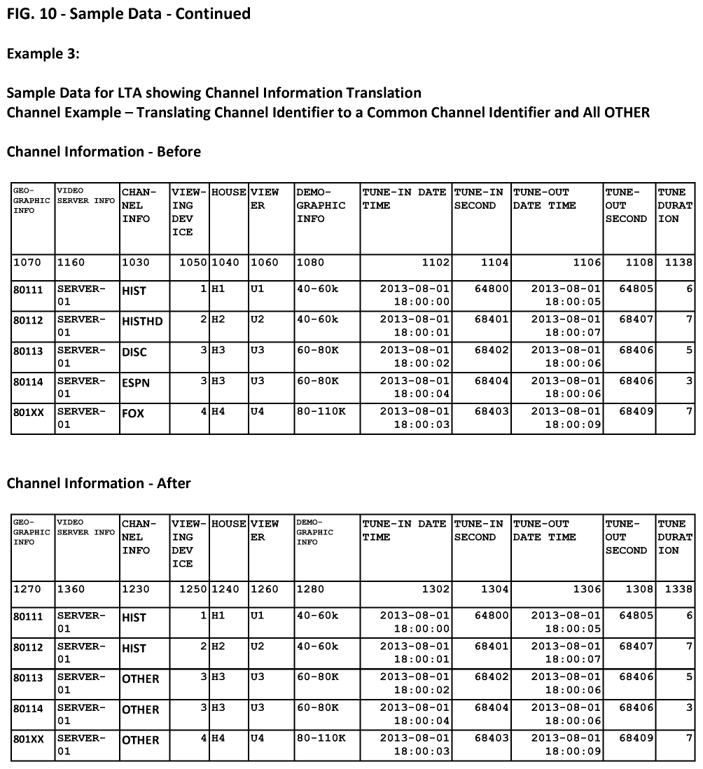

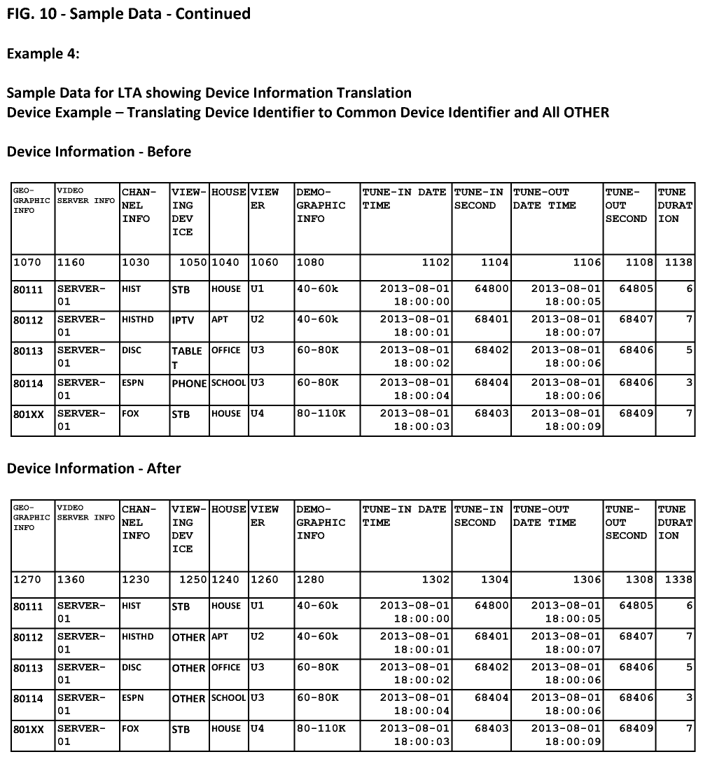

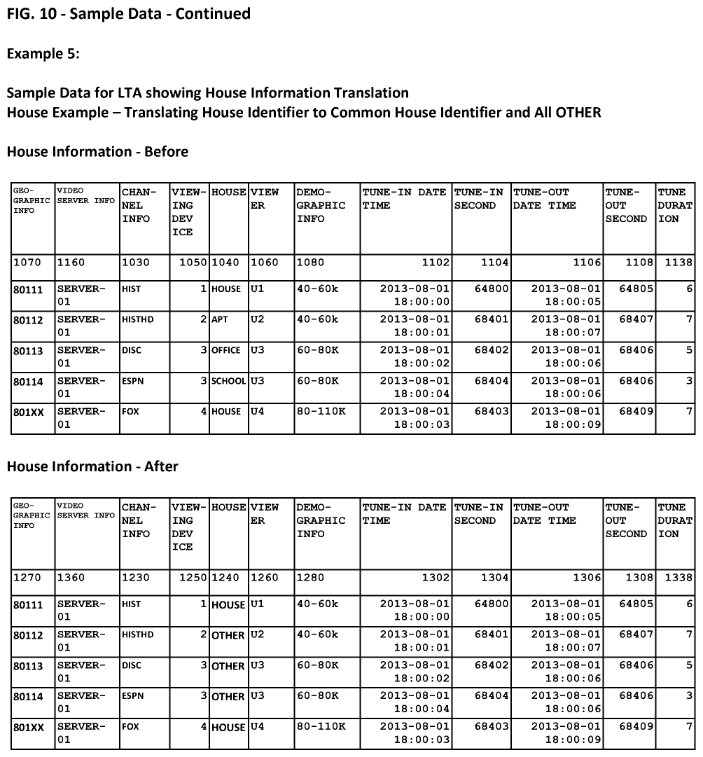

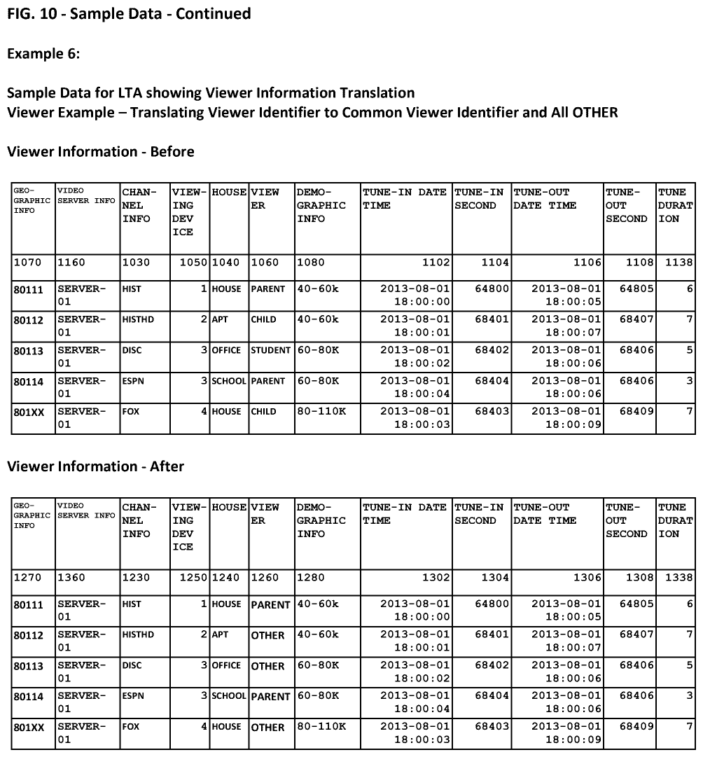

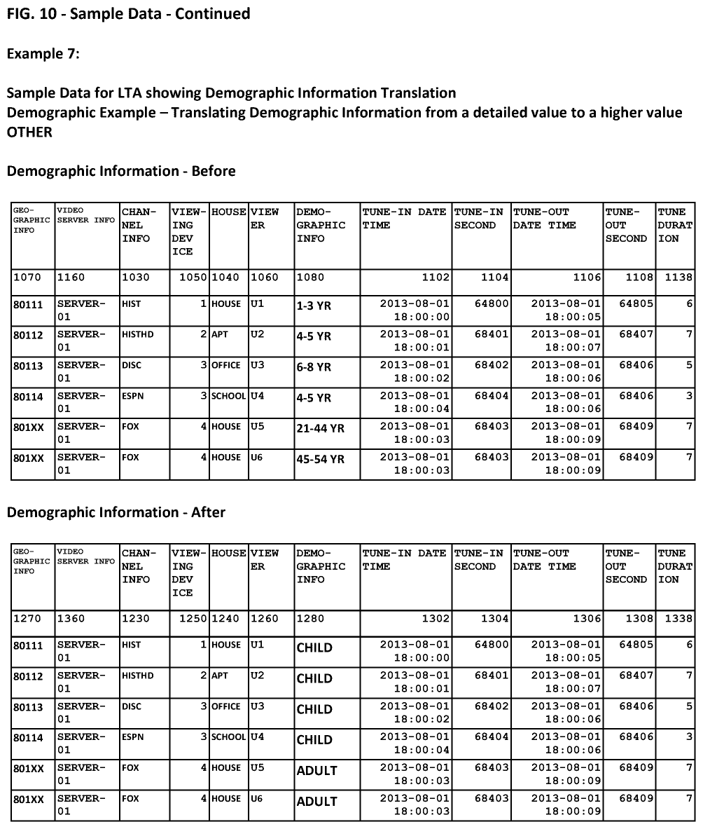

FIG. 10 illustrates various non-limiting examples which provide ‘Before’ and ‘After’ images of Linear Tuning Activity (LTA) records to illustrate what the Channel Translation Processor 150 and Data Translation Processor 154 do, according to one embodiment.

FIG. 10 Example 1 relates to translating GEOGRAPHIC information, according to one embodiment. The “Before” shows Video Viewing Activity Data File 130 records with detailed Geographic Id's (Zip codes)—reference field 1070.

The “After” shows Prepared Video Viewing Activity Data File 160 records with detailed Geographic Id's (Zip codes) replaced by a higher level code—reference field 1270.

FIG. 10 Example 2 relates to translating CHANNEL information, according to one embodiment. The “Before” shows Video Viewing Activity Data File 130 records with both Standard Definition and High Definition Call Signs—reference field 1030.

The “After” shows Prepared Video Viewing Activity Data File 160 records with detailed call signs replaced by Common Call Signs—reference field 1230.

FIG. 10 Example 3 relates to translating CHANNEL information, according to one embodiment. The “Before” shows Video Program Viewing Activity Data File 130 records with both Standard Definition and High Definition Call Signs and other call signs for the various channels—reference field 1030.

The “After” shows Prepared Video Program Viewing Activity Data File 160 records with the Standard Definition and High Definition Call Signs mapped to a common value for the channel of interest (HIST) and the other call signs mapped to “OTHER”—reference field 1230.

FIG. 10 Example 4 relates to translating VIEWING DEVICE information, according to one embodiment. The “Before” shows Video Viewing Activity Data File 130 records with various kinds of viewing devices (STB, IPTV, TABLET, PHONE)—reference field 1050.

The “After” shows Prepared Video Viewing Activity Data File 160 records with the device type of “STB” unchanged while IPTV, TABLET, PHONE have been mapped to “OTHER”—reference field 1250.

FIG. 10 Example 5 relates to translating HOUSE information, according to one embodiment. The “Before” shows Video Viewing Activity Data File 130 records with various kinds of house information values (HOUSE, APT, OFFICE, SCHOOL)—reference field 1040.

The “After” shows Prepared Video Viewing Activity Data File 160 records with the house information type of “HOUSE” unchanged while APT, OFFICE, and SCHOOL have been mapped to “OTHER”—reference field 1240.

FIG. 10 Example 6 relates to translating VIEWER information, according to one embodiment. The “Before” shows Video Viewing Activity Data File 130 records with various kinds of viewer information values (PARENT, CHILD, STUDENT)—reference field 1060.

The “After” shows Prepared Video Viewing Activity Data File 160 records with the viewer information type of “PARENT” unchanged while CHILD and STUDENT have been mapped to “OTHER”—reference field 1260.

FIG. 10 Example 7 relates to translating DEMOGRAPHIC information, according to one embodiment. The “Before” shows Video Viewing Activity Data File 130 records with various kinds of demographic values (1-3 Y R, 4-5 Y R, 6-8 Y R, 21-44 Y R, 45-54 Y R)—reference field 1080. The “After” shows Prepared Video Viewing Activity Data File 160 records with the demographic values mapped to new, summary values (1-3 Y R, 4-5 YR, 6-8 Y R mapped to “CHILD” and 21-44 Y R, 45-54 Y R mapped to “PARENT”)—reference field 1280.

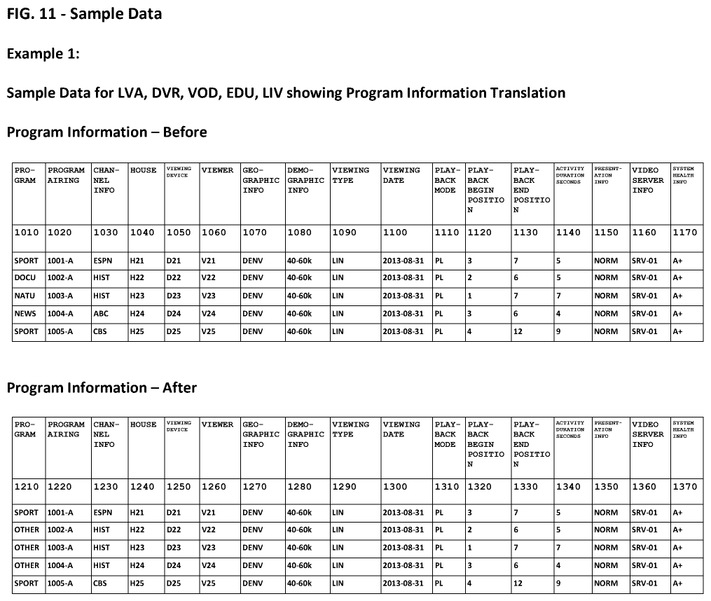

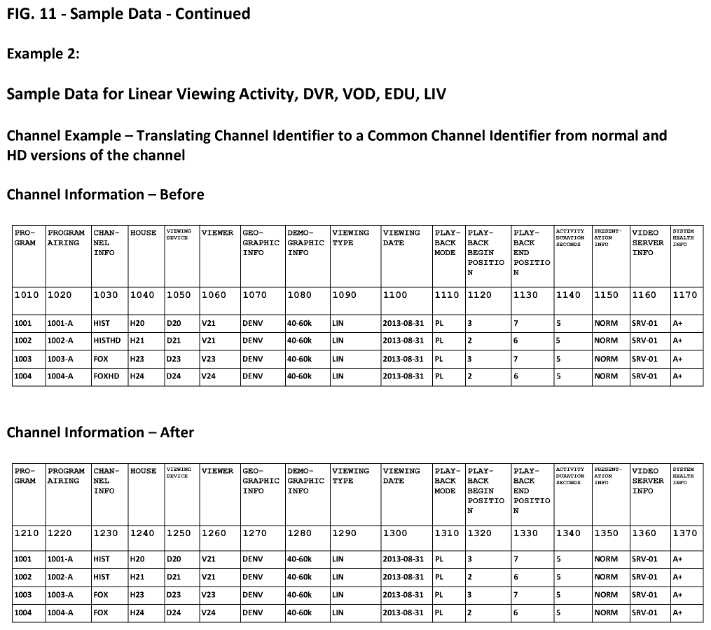

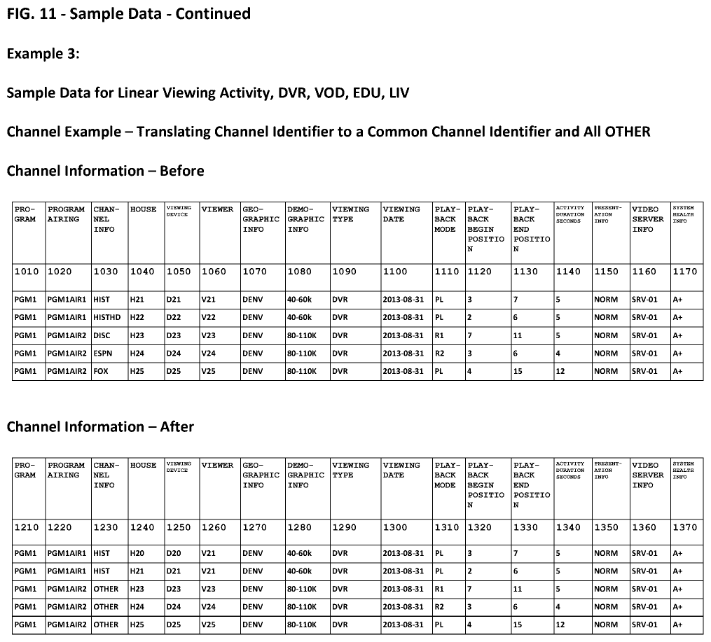

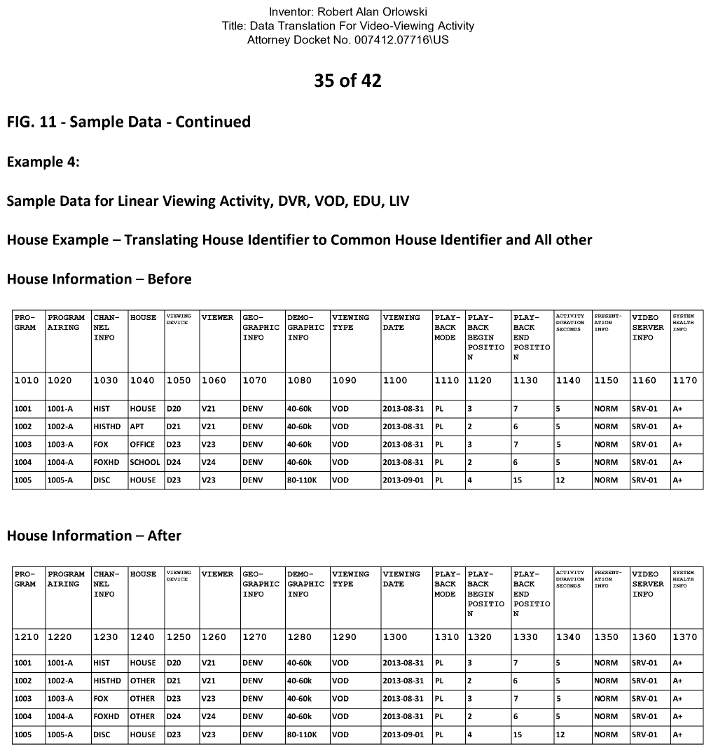

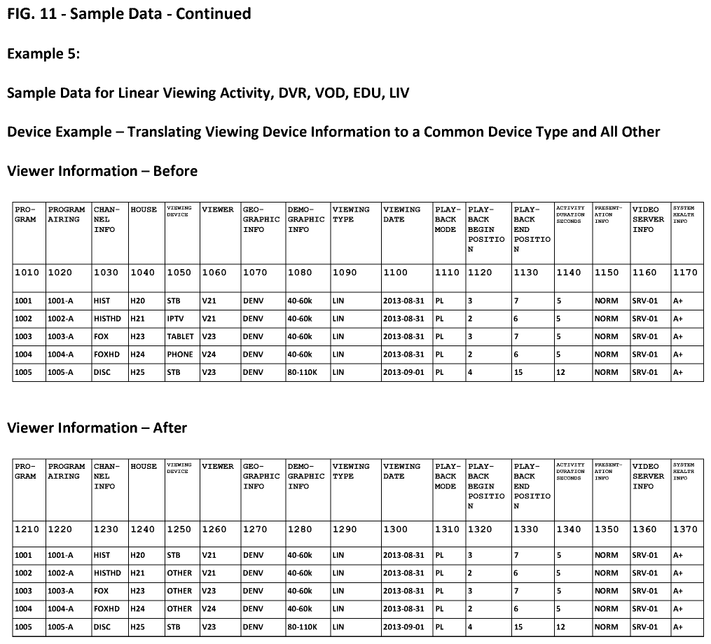

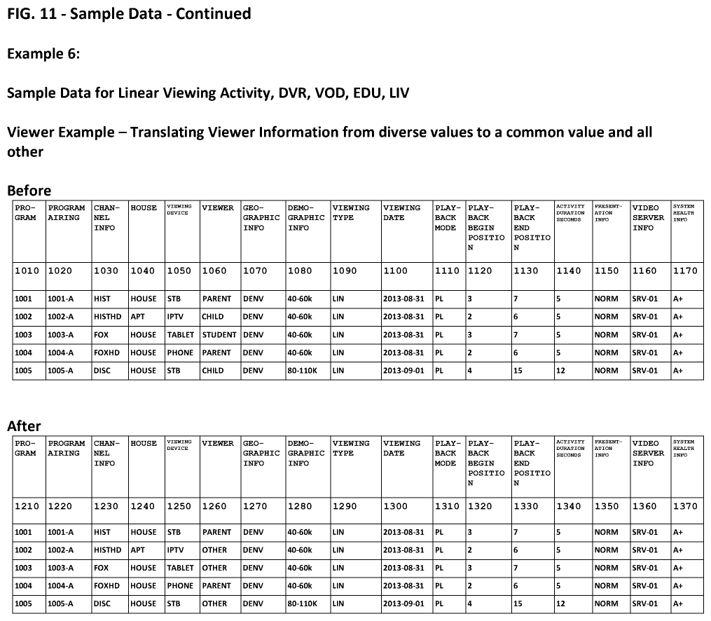

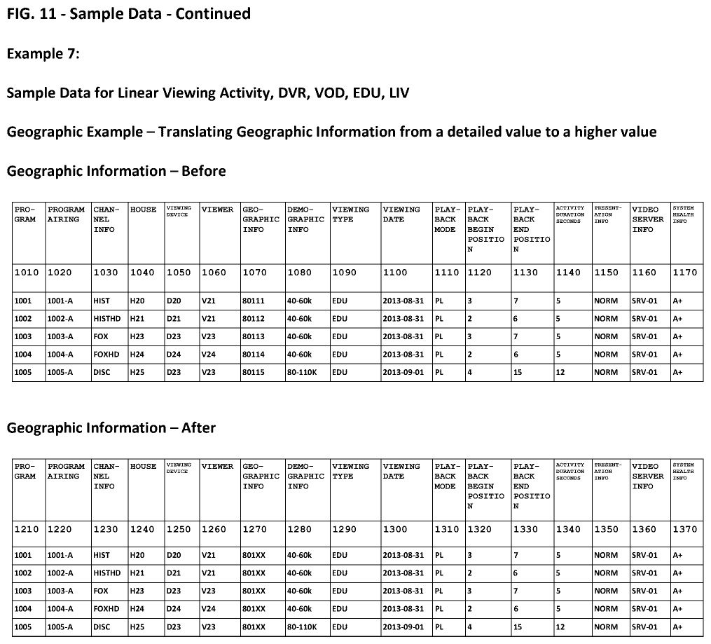

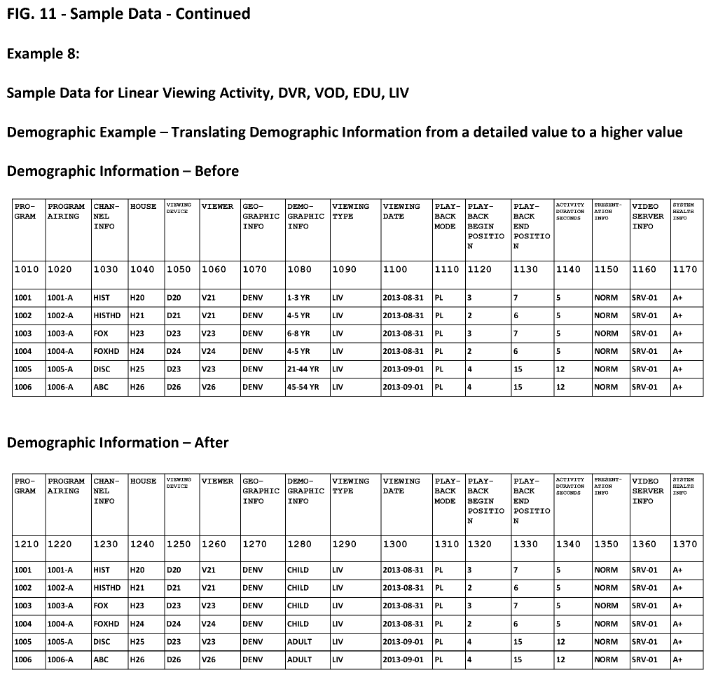

FIG. 11 illustrates various non-limiting examples which provide ‘Before’ and ‘After’ images of Linear Viewing Activity (LVA), Digital Video Recorder viewing activity (DVR), Video On Demand viewing activity (VOD), Educational viewing (EDU), and Live viewing activity (LIV) records to illustrate what the Channel Translation Processor 150 and Data Translation Processor 154 do, according to one embodiment.

FIG. 11 Example 1 relates to translating PROGRAM information, according to one embodiment. The “Before” shows Video Viewing Activity Data File 130 records with a variety of Program information values (SPORT, DOCU, NATU, NEWS)—reference field 1010.

The “After” shows Prepared Video Viewing Activity Data File 160 records with only two values (SPORT and OTHER) with the values of DOCU, NATU, NEWS having been replaced by OTHER—reference field 1210. Thus a more detailed value has been replaced by a summary value.

FIG. 11 Example 2 relates to translating CHANNEL information, according to one embodiment. The “Before” shows Video Viewing Activity Data File 130 records with both Standard Definition and High Definition Call Signs—reference field 1030.

The “After” shows Prepared Video Viewing Activity Data File 160 records with detailed call signs replaced by Common Call Signs—reference field 1230.

FIG. 11 Example 3 relates to translating CHANNEL information, according to one embodiment. The “Before” shows Video Viewing Activity Data File 130 records with both Standard Definition and High Definition Call Signs and other call signs for the various channels—reference field 1030.

The “After” shows Prepared Video Viewing Activity Data File 160 records with the Standard Definition and High Definition Call Signs mapped to a common value for the channel of interest (HIST) and the other call signs mapped to “OTHER”—reference field 1230.

FIG. 11 Example 4 relates to translating HOUSE information, according to one embodiment. The “Before” shows Video Viewing Activity Data File 130 records with various kinds of house information values (HOUSE, APT, OFFICE, SCHOOL)—reference field 1040.

The “After” shows Prepared Video Viewing Activity Data File 160 records with the house information type of “HOUSE” unchanged while APT, OFFICE, and SCHOOL have been mapped to “OTHER”—reference field 1240.

FIG. 11 Example 5 relates to translating VIEWING DEVICE information, according to one embodiment. The “Before” shows Video Viewing Activity Data File 130 records with various kinds of viewing devices (STB, IPTV, TABLET, PHONE)—reference field 1050.

The “After” shows Prepared Video Viewing Activity Data File 160 records with the device type of “STB” unchanged while IPTV, TABLET, PHONE have been mapped to “OTHER”—reference field 1250.

FIG. 11 Example 6 relates to translating VIEWER information, according to one embodiment. The “Before” shows Video Viewing Activity Data File 130 records with various kinds of viewer information values (PARENT, CHILD, STUDENT)—reference field 1060.

The “After” shows Prepared Video Viewing Activity Data File 160 records with the viewer information type of “PARENT” unchanged while CHILD and STUDENT have been mapped to “OTHER”—reference field 1260.

FIG. 11 Example 7 relates to translating GEOGRAPHIC information, according to one embodiment. The “Before” shows Video Viewing Activity Data File 130 records with detailed Geographic Id's (Zip codes)—reference field 1070.

The “After” shows Prepared Video Viewing Activity Data File 160 records with detailed Geographic Id's (Zip codes) replaced by a higher level code—reference field 1270.

FIG. 11 Example 8 relates to translating DEMOGRAPHIC information, according to one embodiment. The “Before” shows Video Viewing Activity Data File 130 records with various kinds of demographic values (1-3 Y R, 4-5 Y R, 6-8 YR, 21-44 Y R, 45-54 Y R)—reference field 1080. The “After” shows Prepared Video Viewing Activity Data File 160 records with the demographic values mapped to new, summary values (1-3 Y R, 4-5 YR, 6-8 Y R mapped to “CHILD” and 21-44 Y R, 45-54 Y R mapped to “PARENT”)—reference field 1280.

### FIG. 11 Summary

Each of the above non-limiting examples shows translating a more detailed value to a less detailed value. By reducing the number of distinct values to be used in the aggregation process, the aggregation run time can be reduced substantially and the computer resource usage can be reduced as well.

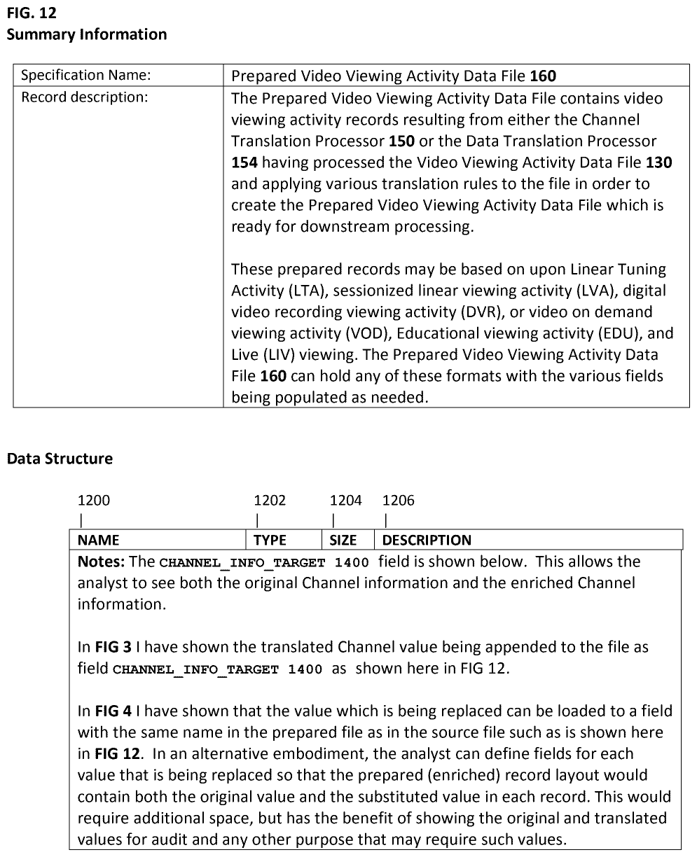

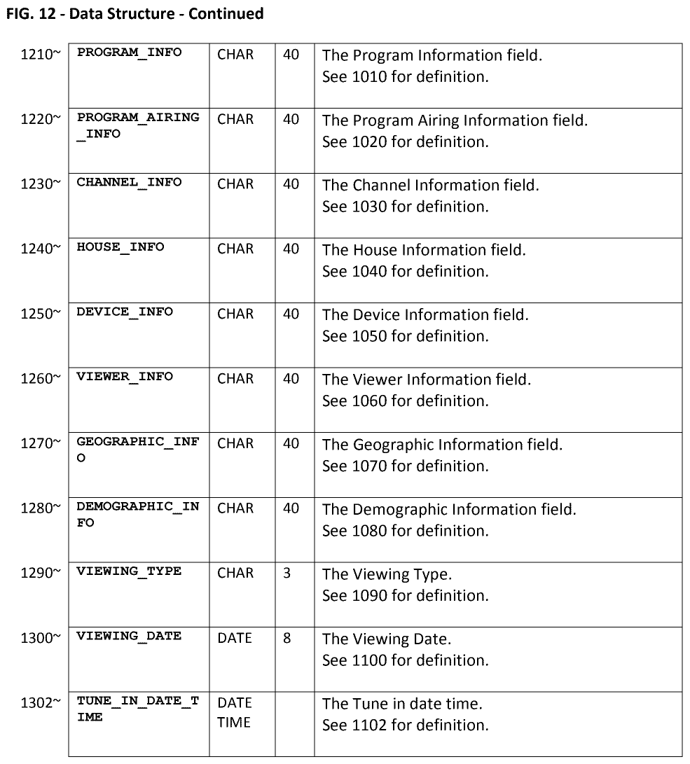

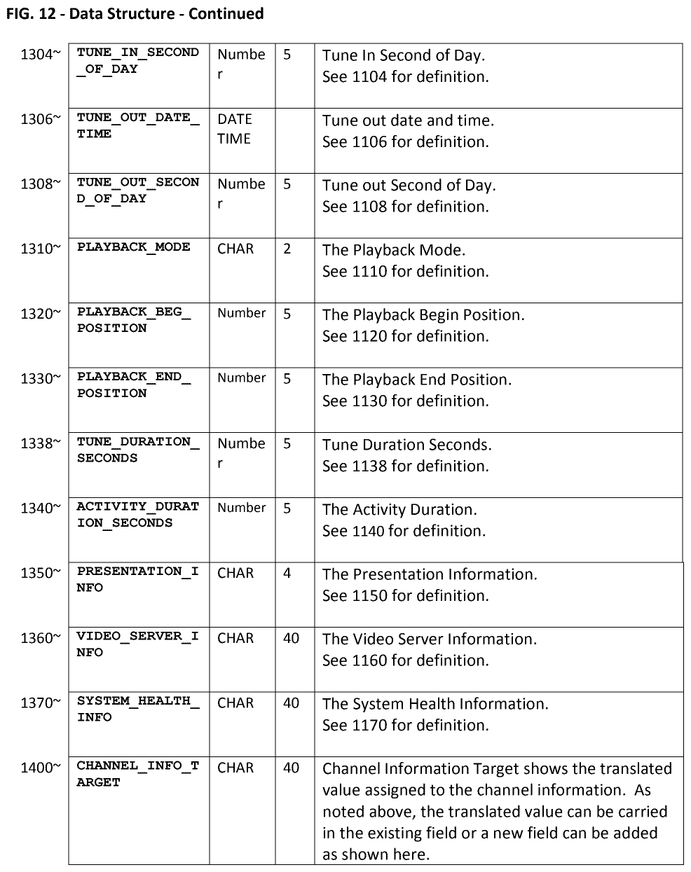

FIG. 12 illustrates an exemplary record layout for a Prepared Video Viewing Activity Data File 160 record created by either the Channel Translation Processor 150 or the Data Translation Processor 154, according to one embodiment. There is Summary Information followed by the Data Structure including field definitions.

### Alternative Embodiments

Although the description above contains much specificity, this should not be construed as limiting the scope of the embodiments but as merely providing illustrations of some of several embodiments. As a nonlimiting example, additional qualifiers may be added along with those provided.

### Scope of Viewer Interaction Data Loaded

I presently contemplate that the Channel Translation Processor 150 and Data Translation Processor 154 will each process viewer interaction data for whatever set of viewing activity is provided to it. This may be one Video Program at a time, one hour of the day, a primetime television viewing period, an entire 24 hour day of viewing, a week of viewing, a weekly program schedule time slot, or another time period decided by the analyst. Another embodiment may simply process viewing activity within the context of a single program, or a single advertisement, or some other combination.

### Identifiers for Data

I presently contemplate using a combination of numeric and mnemonics for the various fields such as program info, program airing info, channel info, house info, device info, viewer info, geographic info, demographic info, viewing type, video server identifiers, system health info, and other similar fields, but another embodiment could use only numeric values as identifiers with links to reference tables for the descriptions of the numeric identifiers or only mnemonic identifiers.

### Programming Algorithm Scope

I presently contemplate executing the algorithms described herein separately in some sequence, but another embodiment could combine multiple simple algorithms into fewer complex algorithms.

### Receiving Date and Time Information

I presently contemplate receiving all of the date and time values in local time, but another embodiment may provide these in Coordinated Universal Time (UTC time).

### General Information

I presently contemplate using variables having the data types and field sizes shown, but another embodiment may use variables with different data types and field sizes to accomplish a similar result.

I presently contemplate using record layouts similar to those defined herein, but another embodiment may use a different record layout or record layouts to accomplish a similar result. As a nonlimiting example, another embodiment may use database tables or other objects instead of record layouts similar to those I have defined herein to accomplish a similar result while still working within the spirit and scope of this disclosure.

### Implementation Information

I presently contemplate using Linux operating system, but another embodiment may use a different operating system.

I presently contemplate using the COBOL language, but another embodiment may use J ava or Python or some other language.

### General Remarks

It will be apparent to those of ordinary skill in the art that various changes and modifications may be made which clearly fall within the scope of the embodiments revealed herein. In describing an embodiment illustrated in the drawings, specific terminology has been used for the sake of clarity. However, the embodiments are not intended to be limited to the specific terms so selected, and it is to be understood that each specific term includes all technical equivalents which operate in a similar manner to accomplish a similar purpose.

In general, it will be apparent to one of ordinary skill in the art that various embodiments described herein, or components or parts thereof, may be implemented in many different embodiments of software, firmware, and/or hardware, or modules thereof. The software code or specialized control hardware used to implement some of the present embodiments is not limiting of the present embodiment. For example, the embodiments described hereinabove may be implemented in computer software using any suitable computer software language type such as, for example, Python or JAVA or COBOL using, for example, conventional or object-oriented techniques. Such software may be stored on any type of suitable computer-readable medium or media such as, for example, a magnetic or optical storage medium. Thus, the operation and behavior of the embodiments are described in COBOL language purely as a matter of convenience. It is clearly understood that artisans of ordinary skill would be able to design software and control hardware to implement the embodiments presented in the language of their choice based on the description herein with only a reasonable effort and without undue experimentation.

The processes associated with the present embodiments may be executed by programmable equipment, such as computers. Software or other sets of instructions that may be employed to cause programmable equipment to execute the processes may be stored in any storage device, such as, for example, a computer system (non-volatile) memory, a compact disk, an optical disk, magnetic tape, or magnetic disk. Furthermore, some of the processes may be programmed when the computer system is manufactured or via a computer-readable medium.

It can also be appreciated that certain process aspects disclosed herein may be performed using instructions stored on a computer-readable memory medium or media that direct a computer or computer system to perform process steps. A computer-readable medium may include, for example, memory devices such as diskettes, compact discs of both read-only and read/write varieties, optical disk drives, memory sticks, and hard disk drives. A computer-readable medium may also include memory storage that may be physical, virtual, permanent, temporary, semi-permanent and/or semi-temporary.

In various embodiments disclosed herein, a single component or algorithm may be replaced by multiple components or algorithms, and multiple components or algorithms may be replaced by a single component or algorithm, to perform a given function or functions. Except where such substitution would not be operative to implement the embodiments disclosed herein, such substitution is within the scope presented herein. Thus any element expressed herein as a means or a method for performing a specified function is intended to encompass any way of performing that function including, for example, a combination of elements that performs that function. Therefore, any means or method that can provide such functionalities may be considered equivalents to the means or methods shown herein.

It can be appreciated that the “data analysis computer system” may be, for example, any computer system capable of running the Translator Processors described herein, whether it be a one node system or a system with thousands of nodes. In an alternative embodiment, it may be a relational database server.

While various embodiments have been described herein, it should be apparent, however, that various modifications, alterations and adaptations to those embodiments may occur to persons skilled in the art with the attainment of some or all of the advantages described herein. The disclosed embodiments are therefore intended to include all such modifications, alterations and adaptations without departing from the scope and spirit of the embodiments presented herein as set forth in the appended claims.

Accordingly, the scope should be determined not by the embodiments illustrated, but by the appended claims and their legal equivalents.

### Conclusions, Ramifications, and Scope

From the description above, a number of advantages of some embodiments of my Channel Translation Processor 150 and Data Translation Processor 154 and its supporting processes become evident:

In this specification I have taught how to reduce the workload on the Hadoop MapReduce framework by translating various values from detailed values to summary values prior to sending the data files to the downstream processes. By implementing the teachings described in this specification, an analyst can reduce the number of unique keys going into the Reduce part of the MapReduce process by 2, 5, 10, and even 100 times. This huge reduction in the unique keys results in a significant reduction in run time and computing resources needed to run the analytical study. This allows an analyst to get answers faster and to run additional analytical studies with the same or less computer hardware.

Additionally, by teaching how to translate multiple kinds of values (program information, channel information, house information, device information, viewer information, geographic information, demographic information) in a single program run, the analyst can create studies which combine multiple dimensions in one run thus being able to slice-and-dice the data in numerous ways to understand how different content is consumed. This provides a framework for creating business value through in-depth analytics.

Also, by implementing my teaching, an analyst can avoid additional expensive database extracts which may otherwise be needed to create the alternative versions of the video viewing activity files which could be fed into downstream processes.

Once the data translations are applied, the resulting prepared file is ready to be used by down-stream processes.

This method of translating various detailed values to summary values prior to feeding the Video Viewing Activity Data files into the downstream processes is a novel technique that has not been taught previously. Using this technique I am able to analyze larger data sets using less hardware than was possible previously.

### Summary

In accordance with one embodiment, I have disclosed a computer-implemented method of using Linear, DVR, VOD, and streaming video viewing activity data as input to a data translation processor which prepares that video viewing activity for more efficient downstream processing by translating detailed values to aggregated values according to analyst defined translation rules in preparation for ingestion by a MapReduce Framework with the result that the MapReduce Framework needs to process less data in order to create analytical studies of second-by-second viewing activity for program, channel, house, device, viewer, demographic, and geographic attributes. The source data may be extracted from a database defined according to the Cable Television Laboratories, Inc. Media Measurement Data Model defined in “Audience Data Measurement Specification” as “OpenCable™ Specifications, Audience Measurement, Audience Measurement Data Specification” document OC-SP-AM D-101-130502 or any similar format. An analyst can use Hadoop to run more studies in less time with less hardware thus gaining greater insights into viewing activity at lower cost.

1. A method comprising:
receiving, by a computing system and from a plurality of video-asset-viewing devices, video-viewing-activity data comprising a plurality of entries;
for at least one entry of the plurality of entries, replacing an attribute associated with a first video-asset-viewing device and a different attribute associated with a second video-asset-viewing device with a common substitute value; and
determining, by the computing system, a video-viewing-activity metric associated with the common substitute value.

2. The method of claim 1, wherein the video-viewing-activity metric is associated with the first video-asset-viewing device and the second video-asset-viewing device outputting a video asset comprises an advertisement.

3. The method of claim 2, wherein the video asset comprises an advertisement.

4. The method of claim 1, further comprising:
determining a mapping of a plurality of attributes to the common substitute value.

5. The method of claim 1, wherein the common substitute value comprises a descriptor describing the attribute associated with the first video-asset-viewing device and the different attribute associated with the second video-asset-viewing device.

6. The method of claim 1, further comprising:
associating each time interval, of a first plurality of time intervals during which the first video-asset-viewing device output a video asset, with the common substitute value.

7. The method of claim 1, wherein the attribute associated with the first video-asset-viewing device comprises a textual value, and wherein the common substitute value comprises a different textual value.

8. The method of claim 1, further comprising:
associating each time interval of a first plurality of time intervals during which the first video-asset-viewing device output a video asset, with an indication of a computing device that sends the video asset to the plurality of video-asset-viewing devices; and
associating each time interval of a second plurality of time intervals, during which the second video-asset-viewing device output the video asset, with an indication of the computing device.

9. The method of claim 1, wherein the replacing the attribute and the different attribute is based on determining that the attribute associated with the first video-asset-viewing device and the different attribute associated with the second video-asset-viewing device satisfy a mapping of attributes to target values.

10. The method of claim 1, further comprising:
receiving, for a data-translation table, one or more user-defined parameters comprising the attribute associated with the first video-asset-viewing device, the different attribute associated with the second video-asset-viewing device, and the common substitute value; and
generating, by the computing system and based on the one or more user-defined parameters, the data-translation table.

11. An apparatus comprising:
one or more processors;
memory storing instructions that, when executed by the one or more processors, cause the apparatus to:
receive, from a plurality of video-asset-viewing devices, video-viewing-activity data comprising a plurality of entries;
for at least one entry of the plurality of entries, replace an attribute associated with a first video-asset-viewing device and a different attribute associated with a second video-asset-viewing device with a common substitute value; and
determine a video-viewing-activity metric associated with the common substitute value.

12. The apparatus of claim 11, wherein the video-viewing-activity metric is associated with the first video-asset-viewing device and the second video-asset-viewing device outputting a video asset comprises an advertisement.

13. The apparatus of claim 12, wherein the video asset comprises an advertisement.

14. The apparatus of claim 11, wherein the instructions, when executed by the one or more processors, further cause the apparatus to:
determine a mapping of a plurality of attributes to the common substitute value.

15. The apparatus of claim 11, wherein the instructions, when executed by the one or more processors, further cause the apparatus to:
associate each time interval, of a first plurality of time intervals during which the first video-asset-viewing device output a video asset, with the common substitute value.

16. The apparatus of claim 11, wherein the instructions, when executed by the one or more processors, further cause the apparatus to:
receive, for a data-translation table, one or more user-defined parameters comprising the attribute associated with the first video-asset-viewing device, the different attribute associated with the second video-asset-viewing device, and the common substitute value; and
generate, based on the one or more user-defined parameters, the data-translation table.

17. A system comprising:
a computing device comprising:
one or more first processors; and
memory storing instructions that, when executed by the one or more first processors, cause the computing device to:
receive, from a plurality of video-asset-viewing devices, video-viewing-activity data comprising a plurality of entries;
for at least one entry of the plurality of entries, replace an attribute associated with a first video-asset-viewing device and a different attribute associated with a second video-asset-viewing device with a common substitute value; and
determine a video-viewing-activity metric associated with the common substitute value; and
a third video-asset-viewing device comprising:
one or more second processors; and
memory storing instructions that, when executed by the one or more second processors, cause the third video-asset-viewing device to send at least a portion of the video-viewing-activity data.

18. The system of claim 17, wherein the instructions stored in the memory of the computing device, when executed by the one or more first processors of the computing device, further cause the computing device to:
determine a mapping of a plurality of attributes to the common substitute value.

19. The system of claim 17, wherein the instructions stored in the memory of the computing device, when executed by the one or more first processors of the computing device, further cause the computing device to:
associate each time interval, of a first plurality of time intervals during which the first video-asset-viewing device output a video asset, with the common substitute value.

20. The system of claim 17, wherein the instructions stored in the memory of the computing device, when executed by the one or more first processors of the computing device, further cause the computing device to:
associate each time interval, of a first plurality of time intervals during which the first video-asset-viewing device output a video asset, with an indication of a computing device that sends the video asset to the plurality of video-asset-viewing devices; and
associate each time interval, of a second plurality of time intervals during which the second video-asset-viewing device output the video asset, an indication of the computing device.

21. The system of claim 17, wherein the instructions stored in the memory of the computing device, when executed by the one or more first processors of the computing device, further cause the computing device to:
receive, for a data-translation table, one or more user-defined parameters comprising the attribute associated with the first video-asset-viewing device, the different attribute associated with the second video-asset-viewing device, and the common substitute value; and
generate, based on the one or more user-defined parameters, the data-translation table.
